(19) United States
(12) Patent Application Publication
(10) Pub. No.: US 2026/0202481 A1
(43) Pub. Date: Jul. 16, 2026

(54) METHOD AND DEVICE FOR DETERMINING THE CAPACITY, INTERNAL RESISTANCE AND OPEN-CIRCUIT VOLTAGE CURVE OF A BATTERY

(71) Applicant: ACCUVICE BETEILIGUNGS GMBH, Offenburg (DE)

(72) Inventor: Wolfgang BESSLER, Offenburg (DE)

(21) Appl. No.: 19/127,961

(22) PCT Filed: Nov. 6, 2023
(86) PCT No.: PCT/DE2023/100825

§ 371 Date: May 7, 2025

(30) Foreign Application Priority Data
Nov. 7, 2022 (DE) 10 2022 129 314.9

(51) Int. Cl. G01R 31/389; G01R 31/367; G01R 31/388; G01R 31/392

(52) U.S. Cl. CPC G01R 31/389; G01R 31/367; G01R 31/388; G01R 31/392

(57) ABSTRACT

The invention relates to a method as well as a device and a computer program for carrying out the method for determining the capacity, the internal resistance and/or the open-circuit voltage curve of a rechargeable battery. The method is based on the measurement of battery voltage Vₘₑₛₛ and battery current Iₘₑₛₛ over a period of time. The measured voltage is applied to a voltage-controlled battery model, which calculates a current I_{mod}. The battery model is provided with arbitrarily assumed values for the parameters to be determined (capacity and/or internal resistance and/or open-circuit voltage curve). As these generally do not correspond to the values of the real battery, there is a difference between the simulated amperage I_{mod} and the measured amperage Iₘₑₛₛ. This difference is used to determine the deviation between the assumed and real values for capacity, internal resistance and/or open-circuit voltage curve using suitable calculation rules. From this and from the assumed values, the real values for capacitance, internal resistance and/or open-circuit voltage curve follow, which can be saved or displayed to a user. If one or more of the parameters are already known from the outset, the known values are used in the model and only the unknown values are determined. The determined values can also be used to update the model. Further measurement data, or a repetition with the same measurement data then allow an increase in measurement accuracy. It is also possible to continuously measure the capacity, internal resistance and/or open-circuit voltage curve over long periods of time and thus evaluate the ageing of the battery.

The invention relates to a method for determining the internal resistance and/or the open-circuit voltage curve and/or the capacity of a rechargeable battery, wherein the method comprises various steps.

Furthermore, the present invention relates to a device for determining the internal resistance and/or the open-circuit voltage curve and/or the capacity of a rechargeable battery with a detection device for detecting measured values for the battery current Iₑₓₚ(t) and the battery voltage Vₑₓₚ(t) of the rechargeable battery, preferably at equidistant time intervals Δt or at predetermined points in time, and an evaluation and control device to which the recorded measured values can be fed, wherein the evaluation and control device is designed to carry out the method for determining the internal resistance and/or the open-circuit voltage curve and/or the capacity of a rechargeable battery. An evaluation and control device is understood here to mean any suitable device which provides this functionality, irrespective of whether in the individual case a control in the narrower sense (i.e. a control of an output variable without feedback) or a regulation (i.e. a control of an output variable using feedback) is effected.

Furthermore, the present invention relates to a computer program for determining the internal resistance and/or the open-circuit voltage curve and/or the capacity of a rechargeable battery for a device, the computer program being designed in such a way that, when the computer program is run in the evaluation and control unit of a device for determining the internal resistance and/or the open-circuit voltage curve and/or the capacity of a rechargeable battery, the method for determining the internal resistance and/or the open-circuit voltage curve and/or the capacity of a rechargeable battery is carried out.

The internal resistance is one of the most important characteristic properties of a battery. It causes a drop in the battery terminal voltage when the battery is loaded with current. There are various methods to measure the internal resistance, e.g. pulse tests or electrical impedance spectroscopy. In a pulse test, the current I₁ and voltage V₁ are measured, then the current or voltage is changed quickly (<1 ms) and the current I₂ and voltage V₂ are measured again a few seconds after the change. The internal resistance R (usually specified in Ω) is calculated as follows

$$R = - \frac{{V}_{2} - {V}_{1}}{{I}_{2} - {I}_{1}} . \qquad ( 1 )$$

The internal resistance is responsible for voltage drops and heat development during battery operation; it typically increases over time (ageing of the battery). As a result, the performance of the battery decreases. It is therefore very important to know the internal resistance over the battery's service life in order to quantify its ageing condition and performance.

The open-circuit voltage curve is another characteristic property of a battery. It describes the course of the open-circuit voltage V⁰(DOD) (OCV) as a function of the depth of discharge (DOD). There are various methods for measuring the open-circuit voltage curve. In a “quasi-OCV” measurement, the battery is fully charged and discharged with very low currents; the open-circuit voltage curve V⁰(DOD) is the average of the measured voltage curves for charging and discharging. The open-circuit voltage curve provides information about the battery chemistry, i.e. which electrode materials are used in the battery, and about the ageing condition and ageing mechanisms. Knowledge of the open-circuit voltage curve is therefore of great importance when characterizing unknown batteries (e.g. used batteries for second-life applications) or when assessing the ageing condition.

The capacity C of a rechargeable battery indicates the amount of charge (typically in ampere hours, Ah) that can be drawn from a fully charged battery. It is another key parameter of a battery. The capacity is typically measured in a laboratory test by completely discharging a full battery with a constant current I and by measuring the capacity according to

$$C = I \cdot {t}_{Entladung} . \qquad ( 2 )$$

In DE 10 2019 127 828 A1, a method for determining the relative capacity C of an aged cell in relation to the capacity CN of a fresh cell (“nominal capacity”) was developed, referred to there as “state of health” (SOH). This method is further developed here to determine the capacity of an unknown battery.

The measurement methods mentioned above (pulse test, quasi-OCV measurement, constant current discharge) require measurement in a laboratory environment with precise measuring devices. This is generally not possible for batteries in practical applications, as they are an integral part of a device (e.g. smartphone, electric car, home storage system) and cannot be removed and transferred to a laboratory, or only with great effort.

Based on this prior art, the invention is based on the object of creating a method for the approximate determination of the capacity and/or the internal resistance and/or the open-circuit voltage curve of a rechargeable battery during normal use of the battery, which has improved accuracy and is also easy to implement in a battery management system. Furthermore, the invention is based on the object of creating a device which enables the aforementioned method to be carried out. Finally, the invention is based on the object of creating a computer program which enables the aforementioned method to be carried out.

The technical object is achieved by the present invention by a method for determining the internal resistance and/or the open-circuit voltage curve and/or the capacity of a rechargeable battery with the following steps. A dynamic, voltage-controlled, mathematical battery model is created, wherein predetermined initial values V⁰_{mod}, R_{mod}, C_{mod} are used for the internal resistance R and/or the open-circuit voltage curve V⁰ and/or the capacity C. The initial values can be chosen arbitrarily. Alternatively, known values can be used if one or more of these parameter values are known and are not to be determined.

The model describes the dependence of the current on the voltage, i.e. it has an internal resistance R_{mod}. Depending on the complexity of the model, the internal resistance results from a single model equation with a single parameter (e.g. Ohm's law) or a combination of model equations and several parameters. The model is voltage controlled. Accordingly, the measured voltage Vₘₑₛₛ is the input variable and the predicted current I_{mod} is the output variable.

According to one embodiment of the invention, the dynamic mathematical battery model may comprise or be developed from a system of equations which comprises, but is not limited to, the following equations:

$$\frac{dDOD}{dt} = \frac{1}{{R}_{s} \cdot C} ( {V}^{0} ( DOD ) - {V}_{mess} )$$

$${I}_{mod} = \frac{1}{{R}_{s}} ( {V}^{0} ( DOD ) - {V}_{mess} )$$

wherein the model comprises the three parameters serial resistance Rₛ, battery capacity C and open-circuit voltage curve V⁰(DOD). The depth of discharge DOD assumes values between 0 and 1, where DOD=0 is a fully charged battery and DOD=1 is a fully discharged battery. This system of equations allows the output variable I_{mod} to be calculated on the basis of the input variable Vₘₑₛₛ. It is therefore a voltage-controlled model (voltage as input variable). Alternatively, more complex models can be used in the new method, e.g. extended equivalent circuit models. Alternatively, the model equations and model parameters can also be specified as a function of the state of charge (SOC), where SOC=1−DOD, SOC=1 is a fully charged battery and SOC=0 is a fully discharged battery, or as a function of another related battery property.

Measured values for the battery current Iₘₑₛₛ(t) and the battery voltage Vₘₑₛₛ(t) of the rechargeable battery are recorded as a function of time over a predetermined period of time T. For some embodiments of the invention, measured values of the battery temperature ϑ(t) are additionally recorded as a function of time over the time period T. The type of charging and discharging (constant or varying current intensity, interruptions, intermediate changes in current direction) in the time period T is basically irrelevant for the method. This means that the method of the present invention can also be used for measured values from practical battery operation. Preferably, the time period T comprises at least one full cycle of the battery, i.e. a complete charge from approximately 0% state of charge to approximately 100% state of charge and a complete discharge from approximately 100% to approximately 0% state of charge. Alternatively, the time period T can also comprise only one full charge cycle, i.e. a complete charge from approximately 0% state of charge to approximately 100% state of charge. Furthermore, the period T can also include only partial cycles, provided that the current is not zero throughout the entire period (no dormant battery). The time period T can also include longer or shorter periods, wherein the longer T, the more accurate the values determined. The predetermined period T can also be determined during the measurement, for example by counting the cumulative charge throughput and evaluating the achievement of a predetermined charge throughput as the achievement of a predetermined period T. The predetermined charge throughput can, for example, correspond to the equivalent charge throughput of a full cycle, in which case the time period T corresponds to a so-called equivalent full cycle. With an equivalent full cycle, it is irrelevant between which states of charge or with which cycle depth the battery is operated, only the cumulative charge throughput is relevant.

Measured values for the battery voltage Vₘₑₛₛ(t) are used as input variables for the dynamic, voltage-controlled, mathematical battery model and values for a simulated current I_{mod}(t) are calculated as output variables of the battery model. Typically, both the input values, which are the measured values for the battery voltage, and the output values of the battery model, which are the simulated values for the current, take the form of a set of discrete-time measured and output values respectively. In other words, the input values are a time-discrete series of measurements of the battery voltage and the output values are a time-discrete series of values of the simulated amperage.

Using the values for the simulated current I_{mod}(t) and the measured values recorded for the current Iₘₑₛₛ(t), values for the internal resistance R_{cal} and/or the open-circuit voltage curve V⁰_{cal} and/or the capacitance C_{cal} are determined using a predefined calculation rule in each case. A separate calculation rule is used for each of the determined variables. The values for the simulated current I_{mod}(t) and the recorded measured values for the current Iₘₑₛₛ(t) are used in such a way that a deviation of the respective associated values from one another is used in the calculation rule. The deviation can preferably be a difference between the values for the simulated current I_{mod}(t) and the measured values for the current Iₘₑₛₛ(t) or a quotient of these. The calculation rules only require the simulated current I_{mod}(t) and the measured values for the current Iₘₑₛₛ(t) for an exact determination of the values for the internal resistance R_{cal} and/or the open-circuit voltage curve V⁰_{cal} and/or the capacitance C_{cal}. The method of the present invention can thus be carried out not only under laboratory conditions, but during any everyday use of the battery.

According to a further embodiment of the invention, the method may comprise at least two iteration steps, wherein each iteration step comprises performing the complete method according to the first embodiment. I.e. Creating a dynamic, voltage-guided, mathematical battery model, wherein predetermined initial values V⁰_{mod}, R_{mod}, C_{mod} are used for the internal resistance R and/or the open-circuit voltage curve V⁰ and/or the capacitance C, acquiring measured values for the battery current Iₘₑₛₛ(t) and the battery voltage Vₘₑₛₛ(t) of the rechargeable battery over a predetermined period T, using the measured values for the battery voltage Vₘₑₛₛ(t) as an input variable for the dynamic, voltage-controlled, mathematical battery, voltage-controlled mathematical battery model, calculating values for a simulated current I_{mod}(t) as an output variable of the battery model and determining calculated values for the internal resistance R_{cal} and/or the open-circuit voltage curve V⁰_{cal} and/or the capacity C_{cal} in each case using the values for the simulated current I_{mod}(t) and the recorded measured values for the current Iₘₑₛₛ(t) with a predetermined calculation rule in each case. Preferably, in each iteration step except the first, i.e. in each complete execution of all steps of the method, the calculated values determined in the previous iteration step for the internal resistance R_{cal} and/or the open-circuit voltage curve V⁰_{cal} and/or the capacitance C_{cal} are used when creating a dynamic, voltage-controlled, mathematical battery model for the predetermined initial values R_{mod}, ^{V(0)}_{mod} and C_{mod} for the internal resistance R and/or the open-circuit voltage curve V⁰ and/or the capacitance C. Such an adjustment of the initial conditions for the subsequent iteration step is also called a “model update”. A measurement period T is associated with an iteration step. Alternatively, already known values can also be used as initial values, or only individual values can be updated.

According to a further embodiment of the invention, the method may comprise at least two iteration steps, wherein each iteration step comprises performing steps (a), (c) and (d) of the method according to claim 1. In each, except the first iteration step, the calculated values for the internal resistance R_{cal} and/or the open-circuit voltage curve V⁰_{cal} and/or the capacitance C_{cal} determined in step (d) of the previous iteration step are used in place of the initial values R_{mod}, V⁰_{mod} and C_{mod} for the internal resistance R and/or the open-circuit voltage curve V⁰ and/or the capacitance C determined in step (d) of the previous iteration step. In this embodiment, a data set of measured values is repeatedly evaluated without remeasuring. In this way, available data sets measured in the past can also be evaluated without a physically present battery. The iterations are repeated until the determined values converge. Convergence is achieved, for example, when the determined values from an iteration step differ by less than a specified percentage, e.g. 1%, from the determined values from the previous iteration step.

According to a further embodiment of the invention, the methods are combined in such a way that measured values are recorded over a period of time T₁, then evaluated with several, but at least two, iteration steps until the values sought converge, and this is repeated with a further period of time T₂. The second time period can directly follow the first. The second period can also have a time interval, e.g. one day. In this case, a battery would be measured once a day and the data record would be evaluated iteratively several times. This would monitor the ageing status of the battery.

According to a further embodiment of the invention, the method can be carried out in such a way that, using a deviation between the values for the simulated current I_{mod}(t) and the measured values for the battery current Iₘₑₛₛ(t), deviations ΔR, ΔV⁰, ΔC between the respective specified initial values R_{mod}, V⁰_{mod}, C_{mod} and the respective calculated values R_{cal}, V⁰_{cal}, C_{cal} are determined. The deviations ΔR, ΔRV⁰, ΔC determined in this way and the specified initial values R_{mod}, V⁰_{mod}, C_{mod} for internal resistance R and/or open-circuit voltage curve V⁰ and/or capacitance C are used to determine the calculated values for internal resistance R_{cal} and/or open-circuit voltage curve V⁰_{cal} and/or capacitance C_{cal}. The deviations ΔR, ΔRV⁰, ΔC between the respectively specified initial values R_{mod}, V⁰_{mod}, C_{mod} and the respectively calculated values R_{cal}, V⁰_{cal}, C_{cal} as well as the deviation between the values for the simulated current I_{mod}(t) and the measured values for the battery current Iₘₑₛₛ(t) can in particular be differences. Ratios or other ways of calculating the deviations are also possible. The use of the deviation between the values for the simulated current I_{mod}(t) and the measured values for the battery current Iₘₑₛₛ(t) to determine the deviations ΔR, ΔRV⁰, ΔC between the respective specified initial values R_{mod}, V⁰_{mod}, C_{mod} and the respective calculated values R_{cal}, V⁰_{cal}, C_{cal} makes it possible to determine the calculated values R_{cal}, V⁰_{cal}, C_{cal} for completely arbitrarily selected initial values R_{mod}, V⁰_{mod}, C_{mod}. This makes the method very easy to use, even without any prior knowledge of the battery values. If some values such as capacity, open-circuit voltage curve or internal resistance of the battery are known, these can be used as initial values R_{mod}, V⁰_{mod}, C_{mod} and thus accelerate the determination of the remaining values.

According to a further embodiment of the invention, the following calculation rule can be used to determine the internal resistance R:

$$\frac{d}{dt} ( \frac{Δ R \cdot {I}_{mess}}{b} ) = \frac{{I}_{mod} - {I}_{mess}}{C} ,$$

wherein ΔR is the difference between the internal resistance of the battery model R_{mod} and the calculated value for the internal resistance, R_{cal}b=dV⁰/dDOD is the slope of the open-circuit voltage curve, I_{mod} is the current of the battery model and Iₘₑₛₛ is the detected current of the battery.

According to a further embodiment of the invention, the following calculation rule can be used to determine the open-circuit voltage curve V⁰:

$$\frac{d}{d t} ( \frac{{Δ V}^{0}}{b} ) = - \frac{{I}_{mo d} - {I}_{m e s s}}{C} ,$$

wherein ΔV⁰ is the difference between the open-circuit voltage curve of the battery model

$${V}_{m o d}^{0}$$

and the calculated value for the open-circuit voltage curve

$${V}_{cal}^{0} ,$$

b is the slope of the open-circuit voltage curve, I_{mod} is the current of the battery model and Iₘₑₛₛ is the detected current of the battery.

According to a further embodiment of the invention, the following calculation rule can be used to determine the capacitance C:

$$Δ C = \frac{{\int }_{t = 0}^{T} \vert {I}_{mo d} ( t ) \vert dt}{{\int }_{t = 0}^{T} \vert {I}_{mess} ( t ) \vert dt} ,$$

wherein ΔC is the quotient of the capacity of the battery model C_{mod} and the calculated value for the capacity of the battery C_{cal}, I_{mod} is the amperage of the battery model and Iₘₑₛₛ is the detected amperage of the battery.

According to a further embodiment of the invention, the following calculation rule can be used for the simultaneous determination of the internal resistance R and the open-circuit voltage curve V⁰:

$$\frac{d}{d t} ( \frac{{Δ V}_{t o t}}{b} ) = - \frac{{I}_{m o d} - {I}_{m e s s}}{C}$$

$$with$$

$${Δ V}_{t o t} = {Δ V}^{0} - Δ R \cdot {I}_{m e s s} ,$$

wherein ΔVₜₒₜ is the total voltage difference, ΔV⁰ is the difference between the open circuit voltage curve of the battery model

$${V}_{m o d}^{0}$$

and the calculated value for the open circuit voltage curve

$${V}_{cal}^{0} ,$$

ΔR is the difference between the internal resistance of the battery model R_{mod} and the calculated value for the internal resistance R_{cal}, b the slope of the open circuit voltage curve, I_{mod} is the current of the battery model and Iₘₑₛₛ is the detected current of the battery. The voltage difference due to the internal resistance ΔR and the voltage difference due to the open-circuit voltage curve ΔV⁰ combine to form a total difference ΔVₜₒₜ (the index “tot” for total). With this type of determination, the internal resistance and the open-circuit voltage curve are determined simultaneously, so that only a few cycles are required to determine both parameters very accurately.

According to a further embodiment of the invention, a numerical solution method can be used to calculate the time-discrete values of the difference of the internal resistance ΔRₙ and/or the time-discrete values of the difference of the open-circuit voltage curve

$$Δ {V}_{n}^{0}$$

and/or for the discrete values of the total difference ΔV_{tot,n}. Here, n is the index for the time-discrete values of the measured variables Iₘₑₛₛ(t) and Vₘₑₛₛ(t) at specific discrete points in time tₙ. Preferably, an implicit Euler method is used to solve the equations. However, the method is not limited to a solution by the implicit Euler method, but can also be solved by other numerical solution methods. In this embodiment, the discrete values of the difference of the internal resistance ΔRₙ are calculated according to

$$Δ {R}_{n} = \frac{{b}_{n}}{{I}_{m ess , n}} ( \frac{Δ t}{C} ( {I}_{m o d , n} - {I}_{mess , n} ) + \frac{Δ {R}_{n - 1} \cdot {I}_{m ess , n - 1}}{{b}_{n - 1}} ) ,$$

where bₙ denotes the value of the slope of the open-circuit voltage curve at the time n, bₙ₋₁ denotes the value of the slope of the open-circuit voltage curve at the time n−1, I_{mess,n} denotes the detected value of the current of the battery at the time n, I_{mess,n-1} denotes the detected value of the current of the battery at the time n-1, I_{mod},n denotes the current of the battery model at the time n, Δt denotes the time interval between two successive measurements and ΔRₙ₋₁ denotes the discrete value of the difference of the internal resistance at the time n−1. In this embodiment, the calculation of the discrete values of the difference of the open-circuit voltage curve (ΔVₙ⁰) is carried out according to:

$${Δ V}_{n}^{0} = - \frac{Δ t \cdot {b}_{n}}{C} ( {I}_{m o d , n} - {I}_{m e s s , n} ) + \frac{{Δ V}_{n - 1}^{0} \cdot {b}_{n}}{{b}_{n - 1}} ,$$

wherein ΔVₙ⁰ denotes the discrete value of the difference of the open-circuit voltage curve at time n and ΔVₙ₋₁⁰ denotes the discrete value of the difference of the open-circuit voltage curve at time n−1. In this embodiment, the discrete values of the total difference (ΔV_{tot,n}) are calculated according to:

$${Δ V}_{t o t , n} = - \frac{Δ t \cdot {b}_{n}}{C} ( {I}_{m o d , n} - {I}_{mess , n} ) + \frac{{Δ V}_{tot , n - 1} \cdot {b}_{n}}{{b}_{n - 1}} ,$$

wherein ΔV_{tot,n} is the discrete value of the difference of the total difference at the time n and ΔV_{tot,n-1} is the discrete value of the difference of the total difference at the time n−1.

According to a further embodiment of the invention, the following calculation rule can be used to calculate the capacity with discrete-time values of the current of the battery:

$$Δ C = \frac{{\sum }_{n = 1}^{N} \vert {I}_{mo d , n} \vert Δ t}{{\sum }_{n = 1}^{N} \vert {I}_{mess , n} \vert Δ t} ,$$

wherein N is the number of time steps, Δt is the time between two consecutive measurements, ΔC is the quotient of the capacity of the battery model C_{mod} and the calculated value for the capacity of the battery C_{cal}, I_{mess,n} is the recorded value of the current strength of the battery at the time n and I_{mod,n} is the simulated current strength of the battery model at the time n.

According to a further embodiment of the invention, at least two time-discrete values of the difference of the internal resistance ΔRₙ to an average value of the difference of the internal resistance Δ̅R̅ and/or at least two time-discrete values of the difference of the open-circuit voltage curve ΔVₙ⁰ to an average value of the difference of the open-circuit voltage curve Δ̅V̅⁰̅ are averaged over a measurement period T, wherein n discrete measurements of current Iₘₑₛₛ and voltage Vₘₑₛₛ are carried out in the measurement period T.

According to a further embodiment of the invention, the internal resistance is determined as a function of depth of discharge and/or current and/or temperature R(DOD, I, ϑ), wherein several values, e.g. mean values, of the difference of the internal resistance Δ̅R̅ over the measurement period T are used for the determination, and wherein the mean values of the difference of the internal resistance Δ̅R̅ are determined by averaging section by section over different ranges of the depth of discharge DOD and/or current Iₘₑₛₛ and/or temperature ϑ. This allows a state of charge, current and/or temperature-dependent internal resistance R(DOD, I, ϑ) to be determined. For this purpose, N measured values are measured in the time period T for the current I_{mess,n} and the voltage V_{mess,n} of the battery. Each measured value is assigned the temperature ϑ and depth of discharge DOD of the battery associated with the time. Time-discrete values of the difference in internal resistance ΔRₙ with the same assignment are calculated from the measured values. This means, for example, that a time-discrete value of the difference in internal resistance ΔRₙ has the same assigned value for the temperature ϑ and depth of discharge DOD of the battery as the measured values for the current I_{mess,n} and the voltage V_{mess,n}. The time-discrete values of the difference of the internal resistance ΔRₙ can be averaged in so-called bins for the same temperatures (for example in predetermined steps of e.g. 1 K) or for the same discharge depths (for example in predetermined steps of e.g. 1%) or for the same current strengths (for example in predetermined steps of e.g. 1% of a predetermined nominal current strength, as specified e.g. in a data sheet). These averaged values are used to determine a state of charge, current and/or temperature-dependent internal resistance R(DOD, I, ϑ). This helps in a possible search for the cause of faults or ageing states of the battery.

According to a further embodiment of the invention, the open-circuit voltage curve is determined as a function of the depth of discharge and/or the temperature, V⁰(DOD, ϑ), wherein several mean values of the open-circuit voltage curve Δ̅V̅⁰̅ over the measurement period T are used for the determination, and wherein the mean values of the open-circuit voltage curve Δ̅V̅⁰̅ are determined by averaging section by section over different ranges of the depth of discharge (DOD) and/or the temperature ϑ. For this purpose, N measured values are measured in the time period T for the current/mess,n and the voltage V_{mess,n} of the battery. Each measured value is assigned the temperature ϑ and depth of discharge DOD of the battery associated with the time. Time-discrete values of the difference in the open-circuit voltage curve ΔV⁰ₙ, with the same assignment, are calculated from the measured values. This means, for example, that a time-discrete value of the difference in the open-circuit voltage curve ΔV⁰ₙ has the same assigned value for the temperature 9 and depth of discharge DOD of the battery as the measured values for the current I_{mess,n} and the voltage V_{mess,n}. The time-discrete values of the difference of the open-circuit voltage curve ΔV⁰ₙ can be averaged for the same temperatures (e.g. in 1° C. steps) or discharge depths (e.g. in 1% steps) in so-called bins. These averaged values are used to determine a charge state and temperature-dependent open-circuit voltage curve V⁰(DOD, ϑ). This helps in a possible search for the cause of faults or ageing states of the battery components.

Furthermore, the technical problem of the present invention is solved by a device for determining the internal resistance and/or the open-circuit voltage curve and/or the capacity of a rechargeable battery with a detection device for detecting measured values for the battery current Iₘₑₛₛ(t) and the battery voltage Vₘₑₛₛ(t) and, for some embodiments of the invention, for the battery temperature ϑ(t) of the rechargeable battery, preferably at equidistant time intervals Δt or at predetermined times, and an evaluation and control device into which the recorded measured values can be fed. The device is characterized in that the evaluation and control device is designed to carry out the described method for determining the internal resistance and/or the open-circuit voltage curve and/or the capacity of a rechargeable battery. In particular, the evaluation and control device can be integrated into the battery management system (BMS) used in many modern battery systems, which makes this information available to the user, for example by means of a display.

Furthermore, the technical problem of the present invention is solved by a computer program for determining the internal resistance and/or the open-circuit voltage curve and/or the capacity of a rechargeable battery. The computer program is designed in such a way that, when the computer program is run in the evaluation and control device, the method for determining the internal resistance and/or the open-circuit voltage curve and/or the capacity of a rechargeable battery is carried out.

The invention is explained in more detail below with reference to the embodiments shown in the drawing. The drawing shows:

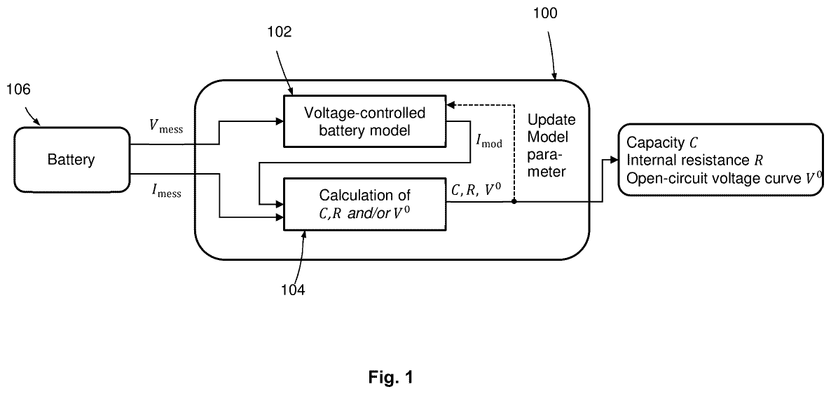

FIG. 1A schematic diagram of the method for determining the internal resistance R, open-circuit voltage curve V⁰ and/or capacity C of a rechargeable battery;

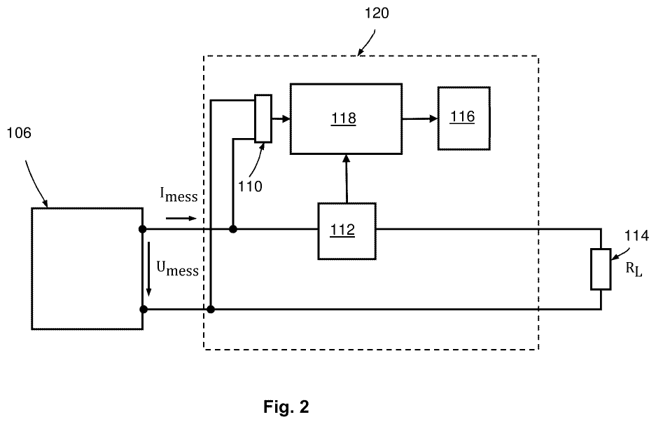

FIG. 2 a schematic block diagram of a battery operated under load with a device according to the invention for carrying out the method;

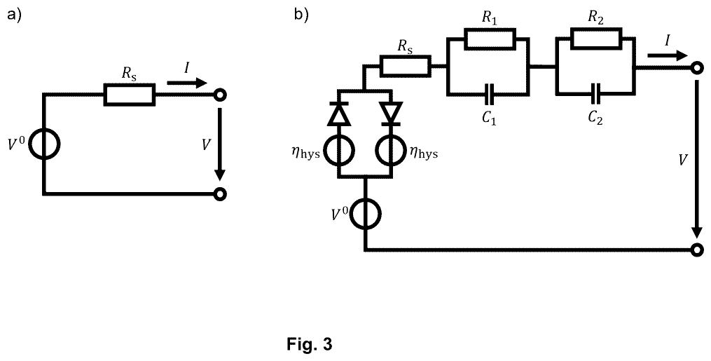

FIG. 3a) a simple equivalent circuit model of a battery;

FIG. 3b) a more complex equivalent circuit model of a battery;

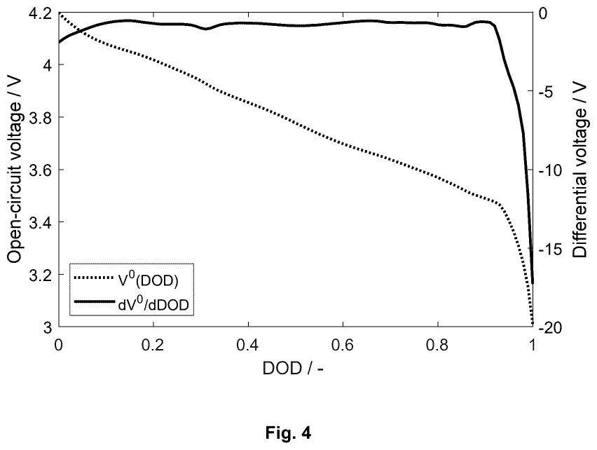

FIG. 4 an experimentally determined open-circuit voltage curve V⁰(DOD) and its derivative dV⁰/dDOD;

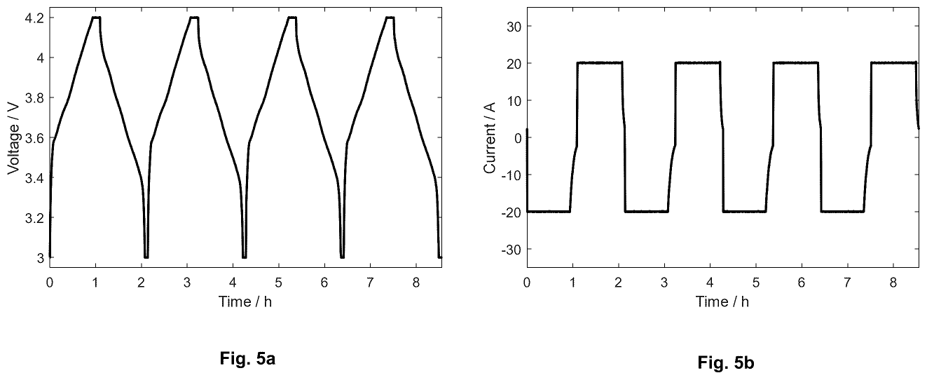

FIG. 5a) the measured voltage Vₘₑₛₛ(t), plotted over time for four consecutive full cycles, starting with a fully discharged battery;

FIG. 5b) the measured current Iₘₑₛₛ(t), plotted over time for four consecutive full cycles, starting with a fully discharged battery;

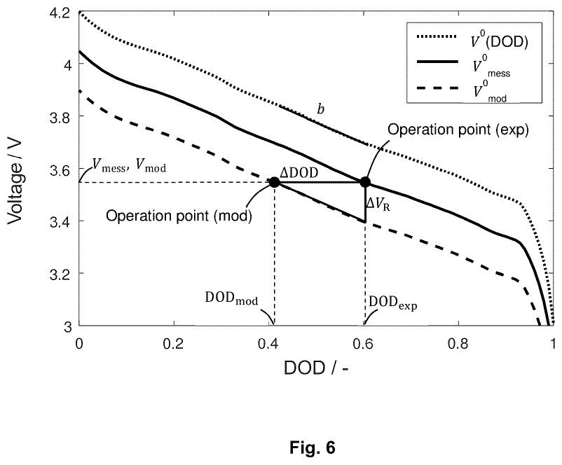

FIG. 6 the open-circuit voltage curve V⁰, the voltage of the real battery Vₘₑₛₛ and the voltage of the battery model V_{mod}, plotted against the depth of discharge DOD;

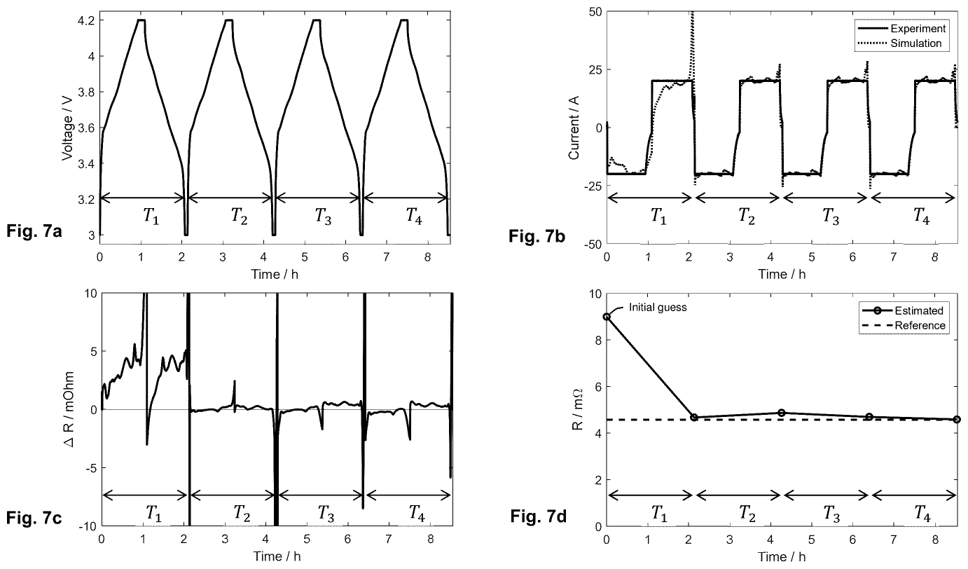

FIG. 7 shows the results of the new method for determining the internal resistance R, using four consecutive experimental full cycles (T₁ to T₄) as an example;

FIG. 7a) the measured voltage Vₘₑₛₛ as the input variable;

FIG. 7b) the measured current Iₘₑₛₛ and simulated current I_{mod} of the voltage-controlled model, plotted against time t;

FIG. 7c) the difference between simulated and experimental resistance ΔR determined according to Eq. (17);

FIG. 7d) the calculated internal resistance R_{cal} of the battery according to Eq. (19) after each time period T; the dashed line is the independently determined reference value for the internal resistance;

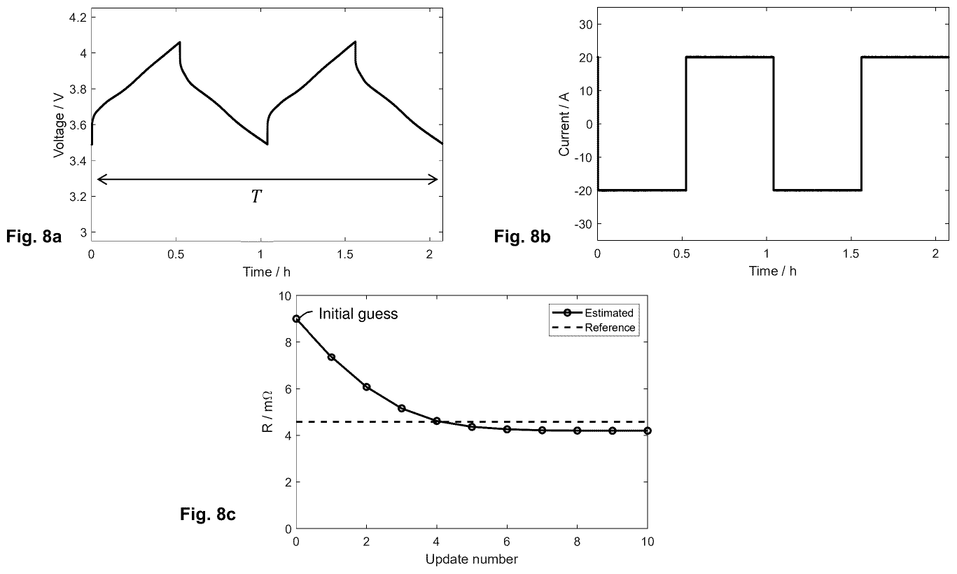

FIG. 8 Demonstration of the new method for determining the internal resistance R, using experimental partial cycles (between 25% and 75% state of charge) as an example;

FIG. 8a) the measured voltage Vₘₑₛₛ, plotted against time t;

FIG. 8b) the measured current Iₘₑₛₛ, plotted against time t;

FIG. 8c) the calculated internal resistance R_{cal} of the battery, starting from an arbitrary initial value (here 9 mΩ), over the course of a total of 10 consecutive model updates;

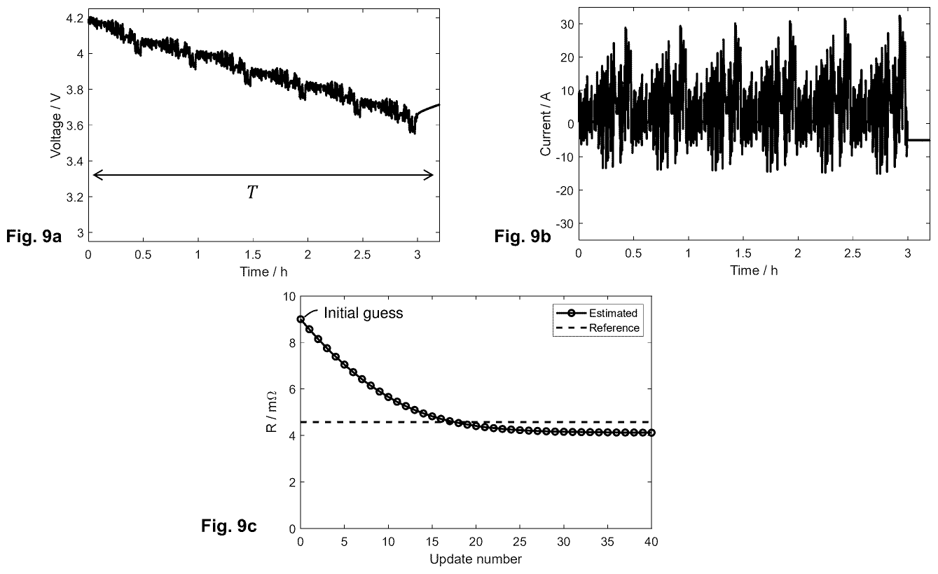

FIG. 9 Demonstration of the new procedure for determining the internal resistance R, using experimental driving cycles in the “Worldwide Harmonized Light-Duty Vehicles Test Procedure” (WLTP) protocol as an example;

FIG. 9a) the measured voltage Vₘₑₛₛ, plotted against time t;

FIG. 9b) the measured, dynamically strongly varying current Iₘₑₛₛ, plotted against time t;

FIG. 9c) the calculated internal resistance R_{cal} of the battery, starting from an arbitrary initial value (here 9 mΩ), over the course of a total of 40 consecutive model updates;

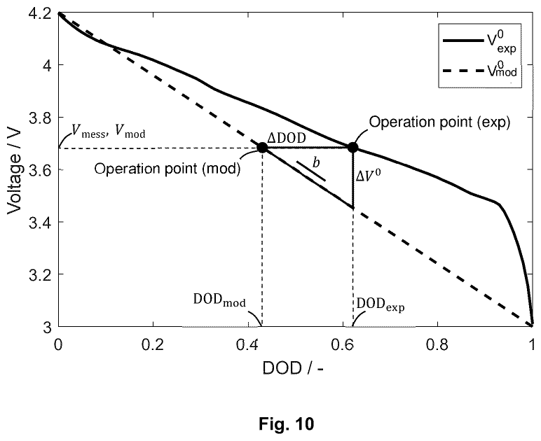

FIG. 10 the real open-circuit voltage curve

$${V}_{exp}^{0}$$

of a lithium-ion battery cell, plotted as voltage versus depth of discharge DOD, and the initial assumption of the open-circuit voltage curve in the battery model

$${V}_{m o d}^{0} ;$$

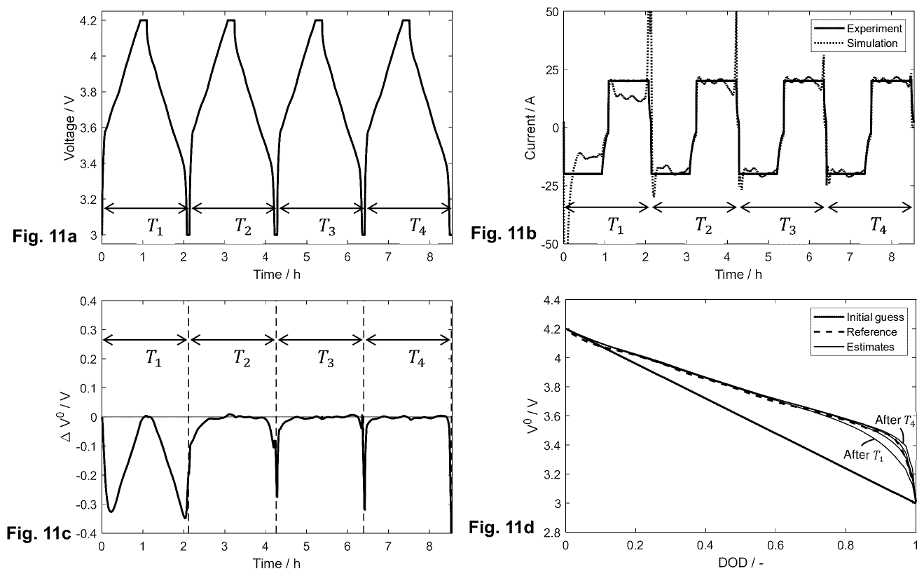

FIG. 11 shows the results of the new method for determining the open-circuit voltage curve V⁰(DOD), using four consecutive experimental full cycles (T₁ to T₄) as an example;

FIG. 11a) the measured voltage Vₘₑₛₛ, plotted against time t;

FIG. 11b) the measured current Iₘₑₛₛ and the simulated current I_{mod} of the voltage-controlled model, plotted against time t;

FIG. 11c) the difference between simulated and experimental open-circuit voltage determined according to Eq. (29) ΔV⁰;

FIG. 11d) the open-circuit voltage curve

$${V}_{cal}^{0} ( DOD )$$

of the battery determined according to Eq. (30) after each period T; the dashed line is the independently determined reference curve;

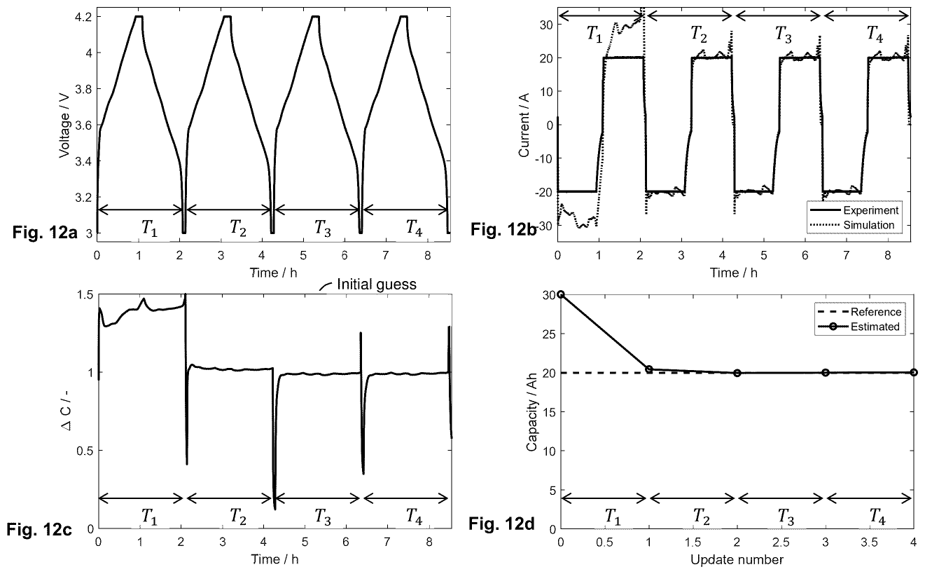

FIG. 12 the results of the new method for determining the capacity C, using four consecutive experimental full cycles (T₁ to T₄) as an example;

FIG. 12a) the measured voltage Vₘₑₛₛ, plotted against time t;

FIG. 12b) the measured current Iₘₑₛₛ and the simulated current I_{mod} of the voltage-controlled model, plotted against time t;

FIG. 12c) shows the difference between the simulated and experimental open-circuit voltage determined according to Eq. (37) ΔC;

FIG. 12d) the determined capacity C_{cal} of the battery, based on an arbitrary starting value of 30 Ah; the dashed line is the independently determined reference value;

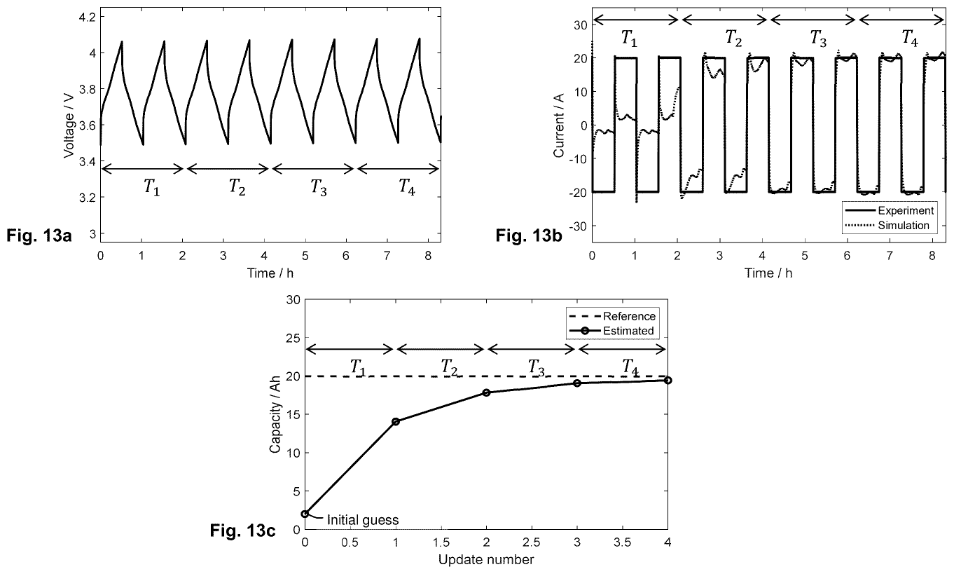

FIG. 13 the results of the new method for determining the capacitance C, using experimental partial cycles as an example;

FIG. 13a) the measured voltage Vₘₑₛₛ, plotted against time t for eight consecutive partial cycles;

FIG. 13b) the measured current Iₘₑₛₛ and the simulated current I_{mod} of the voltage-controlled model, plotted against time t;

FIG. 13c) the determined capacity C_{cal} of the battery, starting from an arbitrary initial value (here C_{mod}=2 Ah); the dashed line is the independently determined reference value.

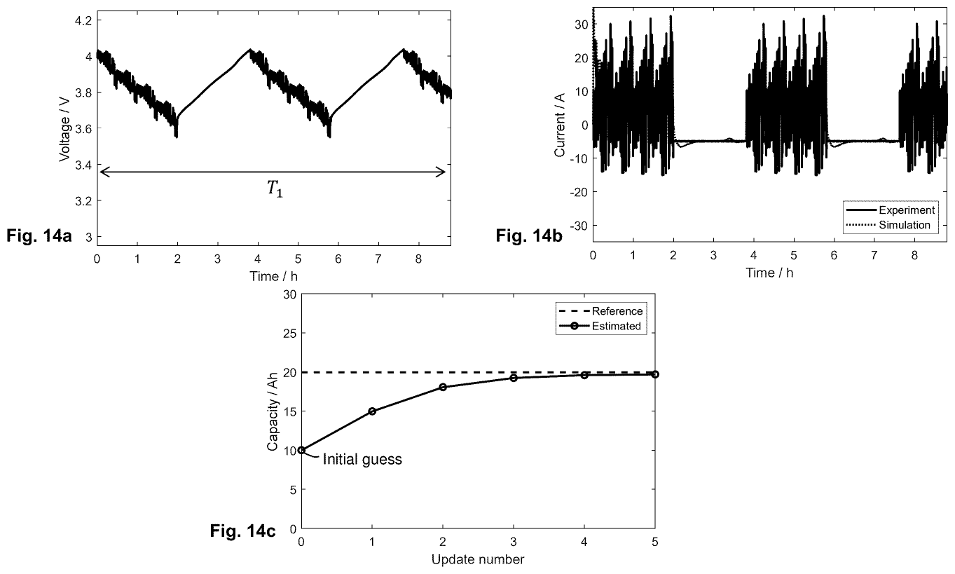

FIG. 14 the results of the new procedure for determining capacity C, using experimental driving cycles in the “Worldwide Harmonized Light-Duty Vehicles Test Procedure” (WLTP) protocol as an example;

FIG. 14a) the measured voltage Vₘₑₛₛ, plotted against time t for several discharges in the WLTP driving cycle and subsequent constant current charging;

FIG. 14b) the measured current Iₘₑₛₛ and the simulated current I_{mod} of the voltage-controlled model, plotted against time t;

FIG. 14c) the determined capacity C_{cal} of the battery, starting from an arbitrary initial value (here C_{mod}=10 Ah); the dashed line is the independently determined reference value;

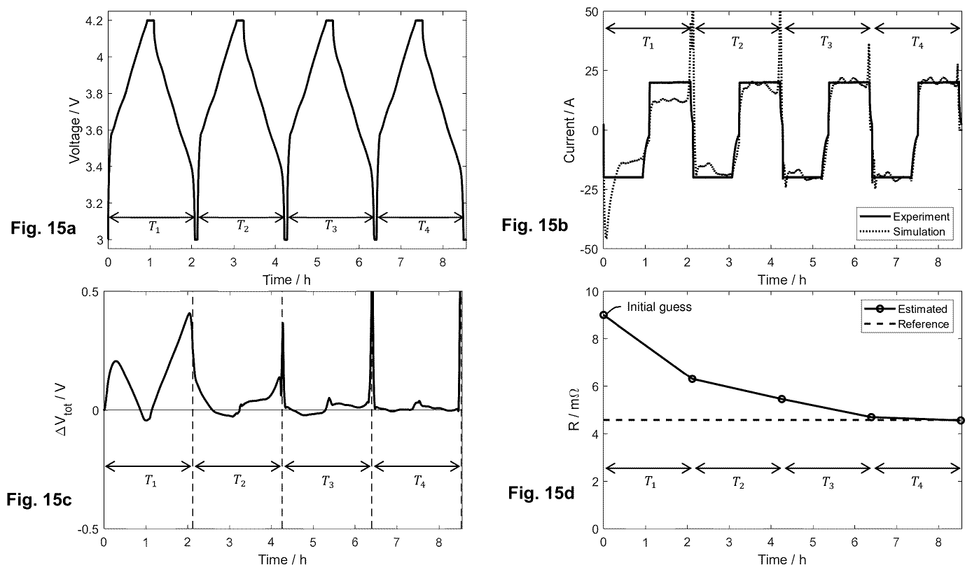

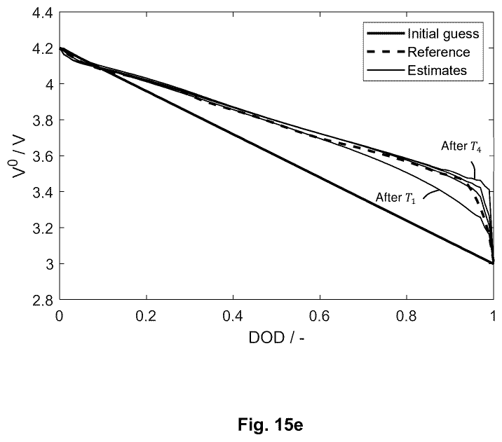

FIG. 15 the results of the new method for the simultaneous determination of the internal resistance R and the open-circuit voltage curve V⁰(DOD), using four consecutive experimental full cycles (T₁ to T₄) as an example;

FIG. 15a) the measured voltage Vₘₑₛₛ, plotted against time t for four consecutive full cycles;

FIG. 15b) the measured current Iₘₑₛₛ and the simulated current I_{mod} of the voltage-controlled model, plotted against time t;

FIG. 15c) the difference between simulated and experimental stress determined according to Eq. (42) ΔVₜₒₜ;

FIG. 15d) the calculated internal resistance R_{cal} of the battery according to Eq. (19) after each time period T; the dashed line is the independently determined reference value for the internal resistance;

FIG. 15e) the open-circuit voltage curve

$${V}_{cal}^{0} ( DOD )$$

of the battery determined according to Eq. (30) after each period T; the dashed line is the independently determined reference curve;

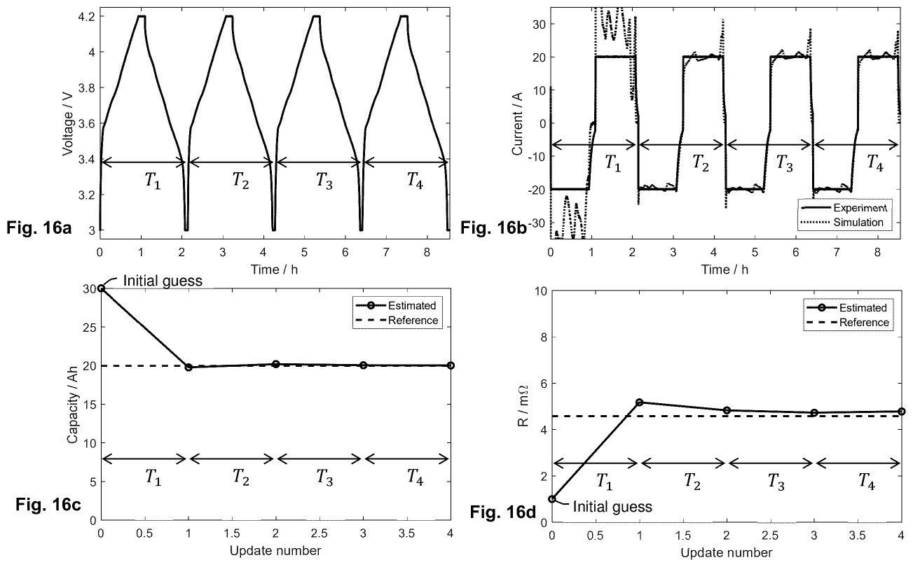

FIG. 16 the results of the new method for the simultaneous determination of the internal resistance R and the capacitance C, using four consecutive experimental full cycles (T₁ to T₄) as an example;

FIG. 16a) the measured voltage Vₘₑₛₛ, plotted against time t for four consecutive full cycles;

FIG. 16b) the measured current Iₘₑₛₛ and the simulated current I_{mod} of the voltage-controlled model, plotted against time t;

FIG. 16c) the determined capacity C_{cal} of the battery after each time period T; the dashed line is the independently determined reference value for the capacity;

FIG. 16d) the calculated internal resistance R_{cal} of the battery according to Eq. (19) after each time period T; the dashed line is the independently determined reference value for the internal resistance;

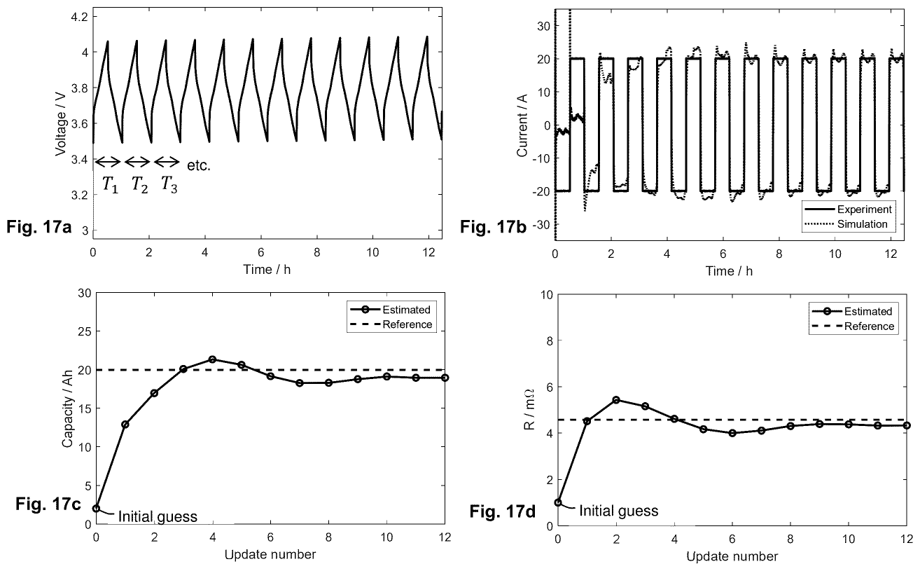

FIG. 17 the results of the new method for the simultaneous determination of the internal resistance R and the capacitance C, using twelve consecutive experimental partial cycles as an example;

FIG. 17a) the measured voltage Vₘₑₛₛ, plotted against time t for twelve consecutive partial cycles;

FIG. 17b) the measured current Iₘₑₛₛ and the simulated current I_{mod} of the voltage-controlled model, plotted against time t;

FIG. 17c) the determined capacity C_{cal} of the battery after each time period T; the dashed line is the independently determined reference value for the capacity;

FIG. 17d) the calculated internal resistance R_{cal} of the battery according to Eq. (19) after each time period T; the dashed line is the independently determined reference value for the internal resistance;

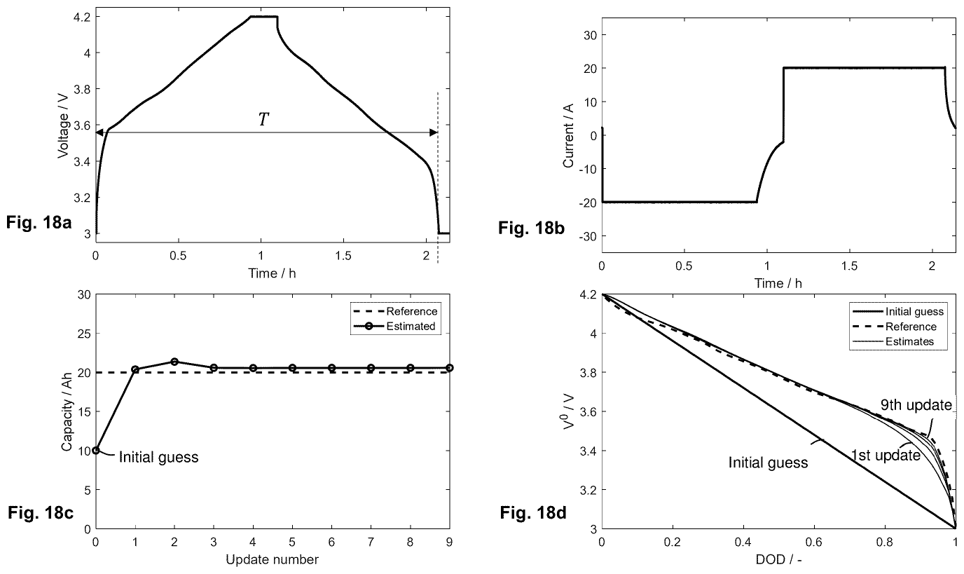

FIG. 18 the results of the new method for the simultaneous determination of capacitance C and open-circuit voltage curve V⁰, using an experimental full cycle as an example;

FIG. 18a) the measured voltage Vₘₑₛₛ, plotted against the time t for a full cycle;

FIG. 18b) the measured current Iₘₑₛₛ, plotted against time t;

FIG. 18c) the determined capacity C_{cal} of the battery, starting from an arbitrary initial value (here C_{mod}=10 Ah) over 9 consecutive model updates; the dashed line is the independently determined reference value for the capacity;

FIG. 18d) the determined open-circuit voltage curve

$${V}_{cal}^{0} ( DOD )$$

of the battery over 9 consecutive model updates; the dashed line is the independently determined reference curve;

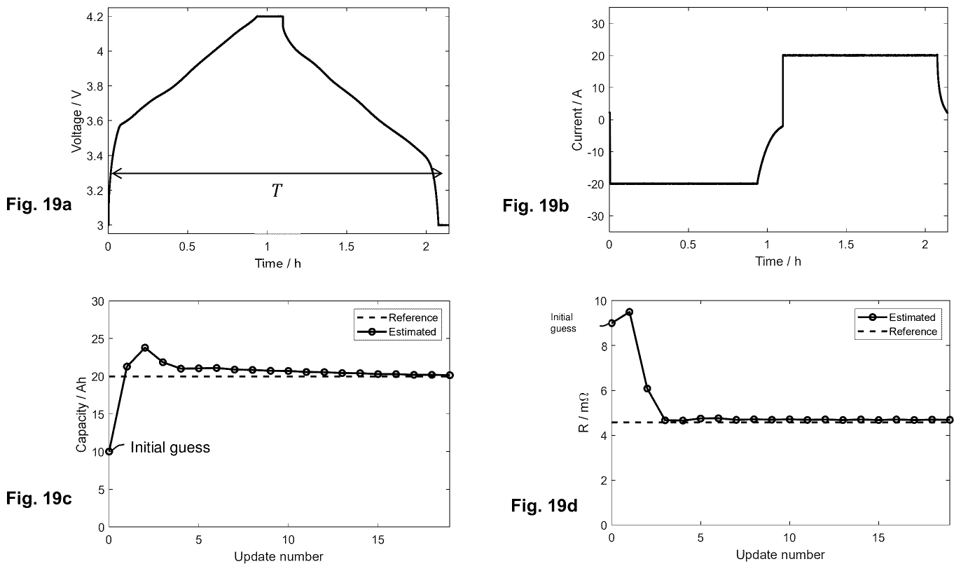

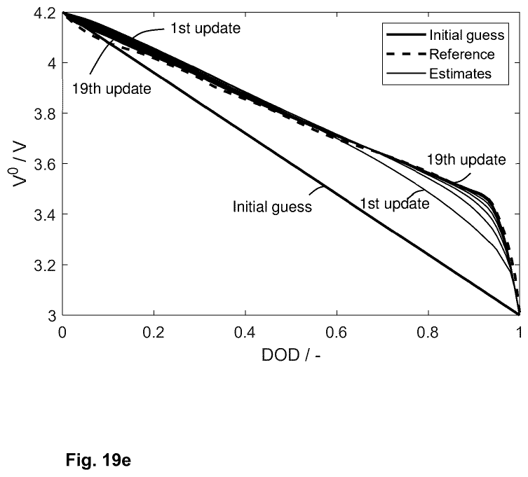

FIG. 19 Results of the new method for the simultaneous determination of capacitance C, internal resistance R and open-circuit voltage curve V⁰, using an experimental full cycle as an example;

FIG. 19a) the measured voltage Vₘₑₛₛ, plotted against the time t for a full cycle;

FIG. 19b) the measured current Iₘₑₛₛ, plotted against time t;

FIG. 19c) the determined capacity C_{cal} of the battery, starting from an arbitrary initial value (here C_{mod}=10 Ah) over 19 consecutive model updates; the dashed line is the independently determined reference value for the capacity;

FIG. 19d) the calculated internal resistance R_{cal} of the battery, starting from an arbitrary initial value of 9 mΩ over 19 consecutive model updates; the dashed line is the independently determined reference value for the internal resistance;

FIG. 19e) the determined open-circuit voltage curve

$${V}_{cal}^{0} ( DOD )$$

of the battery over 19 consecutive model updates; the dashed line is the independently determined reference curve.

FIG. 1 shows a schematic representation of the method. The rechargeable battery 106, the first and second components of the overall algorithm 102, 104 and the overall algorithm 100 itself can be seen. Measured values of the voltage Vₘₑₛₛ(t) of the rechargeable battery 106 are transmitted to the first part of the overall algorithm 102. The first part of the overall algorithm 102 comprises the voltage-guided battery model. In the battery model, arbitrarily assumed initial values are used for the internal resistance R_{mod} and/or the open-circuit voltage curve V⁰_{mod} and/or the capacity C_{mod} to be determined. Values for a simulated current I_{mod}(t) are calculated as the output variable of the battery model from the measured voltage Vₘₑₛₛ(t) and the arbitrary variables. The values of the simulated current I_{mod}(t) and measured values for the battery current Iₘₑₛₛ(t) of the rechargeable battery 106 are transferred to the second part of the overall algorithm 104. In this part, calculated values for the internal resistance R_{cal} and/or the open-circuit voltage curve V⁰_{cal} and/or the capacity C_{cal} are determined each case using the values for the simulated current I_{mod}(t) and the acquired measured values for the current Iₘₑₛₛ(t), each using a predetermined calculation rule. The determined values R_{cal}, V⁰_{cal} and C_{cal} are transferred as an update to the voltage-controlled model, where they replace the assumed values R_{mod}, V⁰_{mod} and C_{mod}. The determined values R_{cal}, V⁰_{cal} and C_{cal} are output as the result of the overall algorithm 100.

As shown in FIG. 2, this overall algorithm 100 can be easily integrated into an existing battery management system. For this purpose, the battery management system (not shown) only needs to contain an evaluation and control unit 120 for carrying out the method. The evaluation and control unit 120 comprises a unit 110 for measuring the battery voltage Uₘₑₛₛ, which is connected to the terminals (poles) of the rechargeable battery 106. Furthermore, the evaluation and control unit 120 comprises a unit 112 for measuring the battery current Iₘₑₛₛ, which can be designed in any desired manner. For example, the unit 112 may comprise a shunt resistor which is located in the current path between the battery terminals and any load R_{L}, which is also designated by the reference sign 114. The unit 112 may thereby be configured to measure the voltage across the shunt resistor and to calculate the current from the measured voltage drop and the resistance value of the shunt resistor. In a further embodiment of the invention, the evaluation and control unit 120 may also comprise a device for detecting the temperature of the battery (not shown).

The evaluation and control unit 120 can also comprise a display unit 116 on which the determined values are displayed. The evaluation and control unit 120 comprises a computing unit 118, which may for example be designed as a microprocessor unit, for performing the calculations required for implementing the method. The microprocessor unit can also have an analog/digital converter, which samples the analog variables Uₘₑₛₛ and Iₘₑₛₛ supplied to it over time and converts them into digital values.

The battery model used in the process must be capable of predicting the current over time for a given voltage curve. To do this, the model must have the following properties. The model describes the dependence of the voltage on the state of charge (SOC) or a related parameter such as the depth of discharge (DOD), the available residual charge or the available residual energy. A necessary model parameter for this is the capacity C of the battery. Another necessary model parameter is the open-circuit voltage curve V⁰(DOD). The model describes the dependence of the voltage on the current, i.e. it has an internal resistance R_{mod}. Depending on the complexity of the model, the internal resistance results from a single model equation with a single parameter (e.g. Ohm's law) or a combination of model equations and several parameters. The internal resistance could be determined by a pulse test applied to the model according to equation (1). The model is voltage controlled. Accordingly, the measured voltage Vₘₑₛₛ is the input variable and the predicted current I_{mod} is the output variable.

There are many different modelling approaches that meet these requirements, e.g. equivalent circuit models or physico-chemical models. A simple equivalent circuit model that is sufficient for demonstrating the method is shown in FIG. 3 a). It consists of a voltage source V⁰ and a serial resistor Rₛ. This model is described mathematically by a differential-algebraic system of equations:

$$\frac{d D O D}{d t} = \frac{1}{{R}_{s} \cdot C} ( {V}^{0} ( DOD ) - {V}_{m e s s} ) , \qquad ( 3 )$$

$${I}_{m o d} = \frac{1}{{R}_{s}} ( {V}^{0} ( DOD ) - {V}_{m e s s} ) . \qquad ( 4 )$$

The model has three parameters: serial resistance Rₛ, battery capacity C and open-circuit voltage curve V⁰(DOD). The depth of discharge DOD assumes values between 0 and 1, where DOD=0 is a fully charged battery and DOD=1 is a fully discharged battery. The DOD is directly related to the state of charge (SOC):

$$SOC = 1 - DOD . \qquad ( 5 )$$

The state of charge SOC is a commonly used variable to indicate how full the battery is. The system of equations (3) and (4) allows the output variable I_{mod} to be calculated based on the input variable Vₘₑₛₛ. It is therefore a voltage-based model (voltage as input variable).

Other, more complex models are also suitable for use in the new method, e.g. extended equivalent circuit models as in FIG. 3b). By using prior knowledge about the battery in more complex models, e.g. the assumption of voltage hysteresis η_{hys}, the accuracy of the method can be increased. The equivalent circuit in FIG. 3b) is an example of a model in which the internal resistance R_{mod} follows from several model elements, here from the R₍ₛ₎₋(RC)₍₁₎₋(RC)₂ chain.

For the demonstration of the present method, experiments were carried out with commercial lithium-ion pouch cells with a nominal voltage of 3.75 V and a nominal capacity of 20 Ah. The cells have a negative electrode made of graphite and a positive electrode made of a mixture of lithium nickel manganese cobalt oxide (NMC) and lithium manganese oxide (LMO). The cells were measured at 25° C. ambient temperature. Three different measurement protocols were carried out. The data from these measurements form the basis for all the methods presented here
1. Full cycles: CCCV discharge to 3.0 V, CCCV charge to 4.2 V, 1C rate, C/10 cut-off current, no pause) for several cycles, starting with a fully discharged battery. This measurement data is shown in FIG. 5.
2. Partial cycles: CC discharge and charge between 25% and 75% state of charge for several partial cycles.
3. Driving cycles: Starting from a fully charged battery, a dynamic load profile was created based on the “Worldwide Harmonized Light-Duty Vehicles Test Procedure” (WLTP). This profile contains rapid successive discharging and charging phases resulting from the acceleration and braking processes of an electric vehicle.

Furthermore, a quasi-OCV measurement was carried out at a rate of 0.05 C. The resulting open-circuit voltage curve V⁰(DOD) and its derivative dV⁰/dDOD are shown in FIG. 4 and serve as a reference for the new method. The open-circuit voltage curve V⁰(DOD) is shown in dotted line as a voltage plotted against the depth of discharge DOD. The curve shows an almost linear discharge of the battery until shortly before complete discharge. The derivative of the open-circuit voltage curved V⁰/dDOD is shown as a solid line and plotted as a voltage over the depth of discharge DOD. The voltage for the derivative can be read off the axis on the right-hand side of the diagram. The curve shows an almost constant progression until shortly before complete discharge.

The internal resistance was determined independently from the full cycles at 1 C according to

$$R = \frac{{\overline{V}}_{chg} - {\overline{V}}_{dis}}{2 \cdot I} \qquad ( 6 )$$

with V̅_{chg} as the average charging voltage between 25% and 75% SOC, V̅_{dis} the average discharging voltage between 75% and 25% SOC and I=20 A. A value of R=4,579 mΩ was determined. The capacity of the battery was also determined from the full cycles at C=19.96 Ah and therefore corresponds almost exactly to the nominal capacity of 20 Ah. These values for C and R also serve as a reference for the new method. In the following, the new method is applied in particular to measured values from four consecutive full cycles. These are shown in FIG. 5. The curve of the measured voltage Vₘₑₛₛ(t), plotted against time in Figure a), and the curve of the measured current Iₘₑₛₛ(t), plotted against time in Figure b), are shown. The four full charge cycles are clearly visible. It was started with a fully discharged battery. The procedure is also demonstrated using the partial cycles and the WLTP load profile as examples.

### Determination of the Internal Resistance

The real battery has a real internal resistance, which we denote by R. As a proxy, a value R_{cal} that is very close to the real internal resistance is determined using the method. The model has an assumed internal resistance, which we denote as R_{mod}. We denote the difference as ΔR with

$$Δ R = {R}_{m o d} - {R}_{ca l} . \qquad ( 7 )$$

Due to this difference, the voltage-controlled battery model will have a different current I_{mod} than the real battery. We refer to the measured current of the real battery as Iₘₑₛₛ. The difference between I_{mod} and Iₘₑₛₛ can therefore be used to infer ΔR. This relationship is derived below.

The derivation is based on FIG. 6, which shows the voltage behavior during a battery discharge with a constant current. First, the open-circuit voltage curve V⁰(DOD) is shown, here an example curve of a lithium-ion battery cell with a final charge voltage of 4.2 V and a final discharge voltage of 3.0 V. We assume that the real battery is at an arbitrary operating point, marked in the figure as “operation point exp”, which corresponds to a certain depth of discharge DODₑₓₚ. When discharging with the current Iₘₑₛₛ, the voltage of the real battery Vₘₑₛₛ(DODₑₓₚ) is lower than the open-circuit voltage due to the internal resistance R, namely on the curve Vₘₑₛₛ(DOD) shown in FIG. 6. We assume that the internal resistance of the battery model is greater than that of the real battery, i.e. ΔR>0. The battery model therefore has an even lower voltage V_{mod}(DODₑₓₚ) for the same depth of discharge DODₑₓₚ, namely on the curve V_{mod}(DOD) shown in FIG. 6. We refer to the voltage difference between the two curves as ΔV_{R}=V_{mod}(DODₑₓₚ)−Vₘₑₛₛ(DODₑₓₚ). In the example in FIG. 6, ΔV_{R}<0. We define the current as positive for battery discharge. According to Ohm's law, the following relationship therefore follows

$${Δ V}_{R} = - Δ R \cdot {I}_{m e s s} . \qquad ( 8 )$$

The method presented here uses a voltage-controlled battery model. By definition, the model therefore has the same voltage as the real battery at all times. Shifting the characteristic curves by ΔV_{R} in relation to each other (for the same DODₑₓₚ) results in the model having a different depth of discharge DOD_{mod} compared to the real battery (at the same voltage Vₘₑₛₛ). The model is therefore at the “operation point (mod)” marked in FIG. 6. We refer to the difference in the depths of discharge as ΔDOD with

$$Δ DOD = {DOD}_{m o d} - {DOD}_{ex p} . \qquad ( 9 )$$

In our example, ΔDOD<0. FIG. 6 clearly shows that ΔV_{R} and ΔDOD form a slope triangle. The slope −ΔV_{R}/ΔDOD corresponds to the slope of the characteristic curve dV/dDOD and, because this is shifted parallel to the open-circuit voltage, to the slope of the open-circuit voltage curve dV⁰/dDOD, which we will refer to as b in the following:

$$- \frac{{Δ V}_{R}}{Δ D O D} = \frac{{d V}^{0}}{d D O D} ≡ b \qquad ( 10 )$$

The negative sign is necessary because ΔV<0 and ΔDOD<0, but also b<0. Inserting Eq. (8) into Eq. (10) provides a correlation between ΔDOD and the unknown variable ΔR,

$$Δ DOD = \frac{Δ R \cdot {I}_{m e s s}}{b} \qquad ( 11 )$$

Next, we develop an expression for ΔDOD. The depth of discharge changes over time due to an applied current. This can be described with a simple differential equation, which we apply to both the real battery and the model:

$$\frac{{dDOD}_{exp}}{dt} = \frac{{I}_{mess}}{C} , \qquad ( 12 )$$

$$\frac{{dDOD}_{mod}}{dt} = \frac{{I}_{mod}}{C} . \qquad ( 13 )$$

We subtract Eq. (12) from Eq. (13) and substitute Eq. (9) into

$$\frac{d ( Δ DOD )}{dt} = \frac{{I}_{mod} - {I}_{mess}}{C} . \qquad ( 14 )$$

This equation describes the temporal development of ΔDOD with a difference between simulated and experimental current. We use Eq. (11) and obtain

$$\frac{d}{dt} ( \frac{Δ R \cdot {I}_{mess}}{b} ) = \frac{{I}_{mod} - {I}_{mess}}{C} . \qquad ( 15 )$$

This equation describes the relationship between the desired variable ΔR, the measured variable Iₘₑₛₛ, the output of the voltage-controlled model I_{mod} and the model parameters C and b.

To calculate ΔR, the time derivative of the left-hand side of equation (15) must be integrated. In practical battery operation, the measured variable Iₘₑₛₛ is determined at certain discrete points in time ty. An implicit Euler method is therefore suitable for solving Eq. (15):

$$\frac{Δ {R}_{n} \cdot {I}_{mess , n}}{{b}_{n}} - \frac{Δ {R}_{n - 1} \cdot {I}_{mess , n - 1}}{{b}_{n - 1}} = \frac{Δ t}{C} \cdot ( {I}_{mod , n} - {I}_{mess , n} ) . \qquad ( 16 )$$

Here, n is the current time of the measurement and Δt=tₙ−tₙ₋₁ is the distance in time to the previous measuring point. This equation can be solved according to the required variable ΔR:

$$Δ {R}_{n} = \frac{{b}_{n}}{{I}_{mess , n}} ( \frac{Δ t}{C} ( {I}_{mod , n} - {I}_{mess , n} ) + \frac{Δ {R}_{n - 1} \cdot {I}_{mess , n - 1}}{{b}_{n - 1}} ) . \qquad ( 17 )$$

This equation is the central result of this analysis. It allows the calculation of ΔR from discrete time series of Iₘₑₛₛ and I_{mod}. A value of ΔR is obtained for each time step. If required, this can be averaged over several time steps N according to

$$\overline{Δ R} = \frac{1}{N} {\sum }_{n = 1}^{N} Δ {R}_{n} . \qquad ( 18 )$$

This averaging can also be carried out over certain DOD sections or over sections of current or temperature, so that the DOD, current or temperature dependence of ΔR is obtained. The value to be determined for the internal resistance of the real battery R_{cal} is obtained in a final step according to equation (7) as follows

$${R}_{cal} = {R}_{mod} - \overline{Δ R} . \qquad ( 19 )$$

Up to this point, the derivation is completely independent of the type of battery model used. This only becomes relevant when calculating equation (19). The internal resistance of the model R_{mod} required for this formula is calculated from the model parameters. For the simple equivalent circuit model in FIG. 3a), R_{mod}=Rₘ. For the exemplary complex equivalent circuit model in FIG. 3b), the result is

R_{mod}=Rₛ+R₁+R₂.

In order to increase the accuracy of the method and/or to use the model for further measurement data, the model parameters can then be adjusted (“updated”). For the simple equivalent circuit model in FIG. 3a), this is done in analogy to Eq. (19) according to

$${R}_{s , neu} = {R}_{s} - \overline{Δ R} . \qquad ( 20 )$$

For more complex models, the determined value Δ̅R̅ must be distributed among the model parameters in a suitable manner. For the exemplary complex equivalent circuit model in FIG. 3b), for example, Δ̅R̅ can be subtracted in each case to ⅓ from the three parameters Rₛ, R₁ and R₂.

The result equation (15) shown above was derived on the basis of FIG. 6 assuming a constant current. This assumption was only used to check plausibility and is not a prerequisite for the present procedure. A battery operation with an arbitrarily varying current (discharge or charge) can be divided into short sections of constant current—such a section is, for example, the distance Δt between two measuring points, as used in the discretized form Eq. (17). For infinitesimally short time intervals, the gradient triangle shown in FIG. 6 changes from the difference quotient ΔV/ΔDOD to the differential quotient dV/dDOD. The result equation (15) is therefore exactly valid, regardless of the dynamics and sign of the current.

Using the derived equations, the internal resistance is determined in practice in the following steps. First, a voltage-controlled battery model with known and/or predetermined parameter values for the capacity C_{mod} and the open-circuit voltage curve V_{mod}⁰(DOD) is provided. Arbitrary starting values are assumed for the parameter(s) associated with the internal resistance R of the model (e.g. Rₛ for the simple equivalent circuit model in FIG. 3a). The battery is operated over a period of time T with measurement of the current Iₘₑₛₛ and the voltage Vₘₑₛₛ. The simulated current I_{mod} is then calculated over the period T using the voltage-controlled model. This is followed by the calculation of ΔR according to equation (17). The values ΔRₙ are averaged over the period T to the mean value ΔR. The approximate value R_{cal} is then calculated for the real internal resistance according to Eq. (19). Optionally, the procedure is repeated, wherein the parameter(s) associated with the internal resistance R_{mod} are set to the determined values in the battery model (“model update”). This results in an iterative approximation of the internal resistance of the model to the real internal resistance.

In the following, the procedure is demonstrated using the experimental data already mentioned, using all three data sets (full cycles, partial cycles, driving cycles). The simple equivalent circuit model of FIG. 3a) is used. The capacitance is set to the reference value of C=19.96 Ah and the open-circuit voltage curve is set to the reference curve shown in FIG. 4. The parameter for the serial resistance is set to an arbitrary starting value, here as an example to Rₛ=9 mΩ.

The results for experimental full cycles are shown in FIG. 7. A charge/discharge cycle is selected as the time period T (approx. 2.1 h). FIG. 7a) shows the measured voltage Vₘₑₛₛ as an input variable for the voltage-controlled model. FIG. 7b) shows both the measured current Iₘₑₛₛ and the simulated current I_{mod} from the voltage-controlled model. During the period T₁ (between 0 and 2 h), a clear deviation I_{mod}−Iₘₑₛₛ of the two curves can be seen. FIG. 7c) shows the difference between the simulated and experimental resistance ΔR determined according to Eq. (17) using the data shown in FIG. 7b). The value ΔR varies over time. In the first cycle (between 0 and 2 h) it assumes values around 4 mΩ, with clear peaks particularly at the respective end of charging and discharging. The value averaged over the first cycle duration T₁ is Δ̅R̅ 4.32 mΩ. According to equation (19), the calculated internal resistance R_{cal} of the battery becomes

$${R}_{cal} = {R}_{mod} - \overline{Δ R} = {R}_{s} - \overline{Δ R} = 9 m Ω - 4 , 32 m Ω = 4 , 68 m Ω .$$

This value is very close to the reference value of 4.58 mΩ. The internal resistance can therefore be determined using the new method after the first full cycle. The method has thus been successfully demonstrated.

The serial resistance of the model is now set to the new value according to Eq. (20), R_{s,neu}=Rₛ−Δ̅R̅, before continuing with the second iteration step in the time period T₂. Proceed analogously according to T₂, T₃ and T₄. The determined internal resistances are shown in FIG. 7d), starting from the assumed initial value. The method stabilizes close to the reference value. At the same time, the prediction quality of the voltage-guided model improves (see FIG. 7b) for periods >2 h) and thus ΔR becomes smaller (see FIG. 7c) for periods >2 h).

These results use full cycles. To demonstrate the flexibility of the method, it was also applied to partial cycles (25% to 75% state of charge) and to driving cycles (load on the battery in the electric vehicle). The results are shown in FIG. 8 (partial cycles) and FIG. 9 (driving cycles). The experimental data sets each consist of 2-3 hours of battery operation. We follow the described procedure. The starting value for the serial resistance is selected at Rₛ=9 mΩ. We select the duration of the entire data set as the period T (2.1 h for the partial cycles, 3.2 h for the driving cycles). According to Eq. (19), we thus obtain a new value for R_{cal}. We then update the model according to Eq. (20) and repeat this with the same experimental data from the period T until R_{cal} converges to a constant value. For the partial cycles this is the case after approx. 5 updates, for the driving cycles after approx. 25. The converged values are R_{cal}=4,20 mΩ (partial cycles, FIG. 8d) and R_{cal}=4,14 mΩ (driving cycles, FIG. 9d), these values are close to the reference value of R=4.58 mΩ.

The new method for determining the internal resistance of a rechargeable battery was successfully demonstrated on the basis of each of the data sets shown and its high flexibility with regard to input data was demonstrated.

### Determination of the Open-Circuit Voltage Curve

The real battery has a real open-circuit voltage curve, which we designate as V⁰(DOD). As a proxy, the method is used to determine a value

$${V}_{cal}^{0}$$

that is very close to the real internal resistance. The model has an assumed open-circuit voltage curve, which we denote by

$${V}_{m o d}^{0} .$$

We denote the difference as ΔV⁰ with

$${ΔV}^{0} = {V}_{mod}^{0} - {V}_{cal}^{0} . \qquad ( 21 )$$

All three parameters, ΔV⁰,

$${V}_{mod}^{0} and {V}_{cal}^{0} ,$$

depend on the depth of discharge DOD. Due to the difference, the voltage-controlled battery model will always have a different current I_{mod} than the real battery Iₘₑₛₛ. The difference between I_{mod} and Iₘₑₛₛ can therefore be used to infer ΔV⁰. This relationship is derived below.

FIG. 10 shows two open-circuit voltage curves. The real curve

$${V}_{exp}^{0} ( DOD )$$

is an example of a lithium-ion battery cell with a final charge voltage of 4.2 V and a final discharge voltage of 3.0 V. A linear curve between the end voltages is assumed for the

$${V}_{mod}^{0} ( DOD )$$

model. For a given operating point DODₑₓₚ (marked as “operation point exp.” in FIG. 10), this leads to the difference ΔV⁰; in the example in FIG. 10

$${ΔV}^{0} < 0.$$

The method presented here uses a voltage-controlled battery model. By definition, the model therefore has the same voltage as the real battery at all times. Shifting the characteristic curves by ΔV⁰ in relation to each other (for the same DODₑₓₚ) results in the model having a different depth of discharge DOD_{mod} compared to the real battery (at the same voltage Vₘₑₛₛ). The model is therefore at the “operation point mod” marked in FIG. 10. We refer to the difference in the depths of discharge as ΔDOD with

$$Δ DOD = {DOD}_{mod} - {DOD}_{mess} . \qquad ( 22 )$$

In our example, ΔDOD<0. FIG. 10 clearly shows that ΔV⁰ and ΔDOD form a slope triangle. The slope −ΔV⁰/ΔDOD corresponds to the slope of the characteristic

$${dV}_{mod}^{0} / dDOD ,$$

which we refer to as b:

$$- \frac{Δ {V}^{0}}{Δ DOD} = b \qquad ( 23 )$$

Next, we develop an expression for ΔDOD. The depth of discharge changes over time due to an applied current. This can be described with a simple differential equation, which we apply to both the real battery and the model:

$$\frac{{dDOD}_{exp}}{dt} = \frac{{I}_{mess}}{C} , \qquad ( 24 )$$

$$\frac{{dDOD}_{mod}}{dt} = \frac{{I}_{mod}}{C} \qquad ( 25 )$$

We subtract Eq. (24) from Eq. (25) and substitute Eq. (22) into

$$\frac{d ( Δ DOD )}{dt} = \frac{{I}_{mod} - {I}_{mess}}{C} . \qquad ( 26 )$$

This equation describes the temporal development of ΔDOD with a difference between simulated and experimental current. We use Eq. (23) and obtain

$$\frac{d}{dt} ( \frac{Δ {V}^{0}}{b} ) = - \frac{{I}_{mod} - {I}_{mess}}{C} . \qquad ( 27 )$$

This equation describes the relationship between the desired variable ΔV⁰, the measured variable Iₘₑₛₛ, the output of the voltage-controlled model I_{mod} and the model parameters C and b.

For the solution, the time derivative of the left side of Eq. (27) must be integrated. In practical battery operation, the measured variable Iₘₑₛₛ is determined at certain discrete points in time tₙ. An implicit Euler method is therefore suitable for solving Eq. (27):

$$\frac{Δ {V}_{n}^{0}}{{b}_{n}} - \frac{Δ {V}_{n - 1}^{0}}{{b}_{n - 1}} = - \frac{Δ t}{C} \cdot ( {I}_{mod , n} - {I}_{mess , n} ) . \qquad ( 28 )$$

Here n is the current point in time of the measurement and Δt=tₙ−tₙ₋₁ is the distance in time to the previous measuring point. This equation can be solved according to the required quantity ΔV⁰:

$$Δ {V}_{n}^{0} = - \frac{Δ t \cdot {b}_{n}}{C} ( {I}_{mod , n} - {I}_{mess , n} ) + \frac{Δ {V}_{n - 1}^{0} \cdot {b}_{n}}{{b}_{n - 1}} . \qquad ( 29 )$$

This equation is the central result of this analysis. It allows the calculation of ΔV⁰ from discrete time series of Iₘₑₛₛ and I_{mod}. A value of ΔV⁰ is obtained for each time step. Since ΔV⁰ depends on DOD, average values must be formed section by section (e.g. every 1 DOD percentage point).

The open-circuit voltage curve of the real battery to be determined results in a final step according to Eq. (21) to

$${V}_{cal}^{0} ( DOD ) = {V}_{mod}^{0} ( DOD ) - Δ {V}^{0} ( DOD ) , \qquad ( 30 )$$

wherein

$${V}_{mod}^{0} ( DOD )$$

is the parameter used in the model. In order to increase the accuracy of the method and/or to use the model for further measurement data, the model parameter can then be adjusted (“updated”) according to

$${V}_{neu}^{0} = {V}_{mod}^{0} - Δ {V}^{0} . \qquad ( 31 )$$

In practice, the open-circuit voltage curve is determined in the following steps. First, a voltage-controlled battery model with known parameter values for the capacity C_{mod} and for the parameter(s) associated with the internal resistance R_{mod} (e.g. Rₛ for the simple equivalent circuit model in FIG. 3a) is provided. An arbitrary starting value is assumed for the course of the open-circuit voltage curve

$${V}_{mod}^{0} ( DOD ) ,$$

preferably a linear course between charge and discharge end voltage. The battery is operated over a period of time T with measurement of the current Iₘₑₛₛ and voltage Vₘₑₛₛ. The simulated current I_{mod} is then calculated over the period T using the voltage-controlled model. This is followed by the calculation of ΔV⁰ according to equation (29). The values

$$Δ {V}_{n}^{0}$$

are averaged by section for DOD areas to the mean value Δ̅V̅⁰̅(DOD) over the period T. The approximate value for the real open-circuit voltage curve is then calculated according to Eq. (30). Optionally, the procedure is repeated, wherein the parameter for the course of the open-circuit voltage curve in the battery model is set to the determined value (“model update”). This results in an iterative approximation of the open-circuit voltage curve of the model to the real open-circuit voltage curve.

The averaging of

$$Δ {V}_{n}^{0}$$

can also be carried out section by section for different ranges of measured temperatures. This allows a temperature-dependent open-circuit voltage curve V⁰(DOD, ϑ) to be determined. The open-circuit voltage curve V⁰ depends on the depth of discharge. For complete recording, the time period T must therefore be selected so that the battery has passed through all states of charge between 0% and 100% at least once. If only a partial range is passed through within T, the open-circuit voltage curve can only be determined in this partial range.

In the following, the procedure described is demonstrated using the experimental data already mentioned, specifically using the full cycles (FIG. 5). The simple equivalent circuit model of FIG. 3a) is used. The capacitance is set to the reference value of C 19.96 Ah and the serial resistance to the reference value of Rₛ=4,579 mΩ. The open-circuit voltage curve V⁰(DOD) is set to an arbitrary starting value, namely a linear curve between the final voltages. A charge/discharge cycle is selected as the time period T (approx. 2.1 h).

The results are shown in FIG. 11. FIG. 11a) shows the measured voltage Vₘₑₛₛ as an input variable for the voltage-controlled model, plotted against time. FIG. 11b) shows both the measured current Iₘₑₛₛ and the simulated current I_{mod} from the voltage-controlled model, plotted against time. During the period T₁ (between 0 and 2 h), a clear deviation I_{mod}−Iₘₑₛₛ of the two curves can be seen, which becomes smaller and smaller in the subsequent time periods. FIG. 11c) shows the difference between the simulated and experimental open-circuit voltage ΔV⁰ determined according to Eq. (29) using the data shown in FIG. 11b). The value ΔV⁰ varies over time during the period T₁ (between 0 and 2 h): The values are symmetrical with respect to charging and discharging and exhibit swings down to −0.35 V. These values are averaged section by section for each DOD percentage point over the first cycle duration T₁. From this, the approximate value for the real open-circuit voltage curve V⁰(DOD) is determined according to Eq. (30). FIG. 11d) shows the linear curve assumed at the beginning as a thick solid line and the curve determined according to T₁ as a thin solid line. The latter is already close to the reference curve, which is also shown as a dashed line in FIG. 11d). The open-circuit voltage curve can be determined using the new method after just two full cycles. The method has thus been successfully demonstrated.

After the period T₁, the model is renewed with the determined curve before continuing with the second cycle in the period T₂. Proceed analogously according to T₂, T₃ and T₄. The curves determined are also shown in FIG. 11d). The procedure stabilizes close to the reference curve. At the same time, the prediction quality of the stress-guided model improves (see FIG. 11b) for time periods >2 h) and thus ΔV⁰ becomes smaller (see FIG. 11c) for time periods >2 h).

With these results, the new method for determining the open-circuit voltage curve of a rechargeable battery was successfully demonstrated.

### Determination of the Capacity

The real battery has a real capacity, which we designate as C. As a proxy, the method is used to determine a value C_{cal} that is very close to the real capacity. The model has an assumed capacity, which we denote by C_{mod}. We denote the difference as ΔC with

$$Δ C = \frac{{C}_{mod}}{{C}_{cal}} . \qquad ( 32 )$$

As the capacity assumed in the model does not usually correspond to the real capacity, the voltage-controlled battery model will always have a different current I_{mod} than that of the real battery Iₘₑₛₛ. The difference between I_{mod} and Iₘₑₛₛ can therefore be used to infer ΔC. This relationship is derived below.

The battery is operated over a period of time T. The charge quantity Q_{cal} is calculated by integration according to

$${Q}_{cal} = {\int }_{t = 0}^{T} \vert {I}_{mess} ( t ) \vert dt . \qquad ( 33 )$$

We choose the amount of current to be independent of the type of operation (charge, discharge or combination of both)—only the absolute amount of charge passed is relevant. The voltage-controlled model is subjected to the experimentally measured voltage over the same period of time. The amount of charge passed through the model Q_{mod} is calculated analogously by integration according to

$${Q}_{mod} = {\int }_{t = 0}^{T} \vert {I}_{mod} ( t ) \vert dt . \qquad ( 34 )$$

The quotient of Q_{mod} and Q_{cal} corresponds to the quotient of C_{mod} and C_{cal}, i.e.

$$\frac{{Q}_{mod}}{{Q}_{cal}} = \frac{{C}_{mod}}{{C}_{cal}} . \qquad ( 35 )$$

The combination of equations (32) to (35) results in

$$Δ C = \frac{{\int }_{t = 0}^{T} \vert {I}_{mod} ( t ) \vert dt}{{\int }_{t = 0}^{T} \vert {I}_{mess} ( t ) \vert dt} . \qquad ( 36 )$$

This equation describes the relationship between the desired variable ΔC, the measured variable Iₘₑₛₛ and the output of the voltage-controlled model I_{mod}. For practical application, the integrals in equation (36) must be calculated. In practical battery operation, the measured variable Iₘₑₛₛ is determined at certain discrete points in time tₙ. This results in Eq. (32)

$$Δ C = \frac{{\sum }_{n = 1}^{N} \vert {I}_{mod , n} \vert Δ t}{{\sum }_{n = 1}^{N} \vert {I}_{mess , n} \vert Δ t} \qquad ( 37 )$$

with N as the number of measuring points in the period T and Δt as the time step. This equation is the central result of this analysis. It allows the determination of ΔC from discrete time series of Iₘₑₛₛ and I_{mod}. The capacity of the real battery to be determined results in a final step according to Eq. (32) as

$${C}_{cal} = {C}_{mod} \cdot \frac{1}{Δ C} . \qquad ( 38 )$$

In order to increase the accuracy of the method and/or to use the model for further measurement data, the model parameters can then be adjusted (“updated”). For the simple equivalent circuit model in FIG. 3a), this is done in analogy to Eq. (38) according to

$${C}_{neu} = {C}_{mod} \cdot \frac{1}{Δ C} . \qquad ( 39 )$$

In practice, the capacity is determined in the following steps. First, a voltage-controlled battery model with known parameter values for the parameter(s) associated with the internal resistance R_{mod} (e.g. Rₛ for the simple equivalent circuit model in FIG. 3a) and for the open-circuit voltage curve

$${V}_{mod}^{0} ( DOD )$$

is provided. An arbitrary starting value is assumed for the capacity C_{mod}. The battery is operated over a period of time T with measurement of current Iₘₑₛₛ and voltage Vₘₑₛₛ. The simulated current I_{mod} is then calculated over the period T using the voltage-controlled model. This is followed by the calculation of ΔC according to equation (37). The approximate value for the real capacitance is then calculated according to Eq. (38). Optionally, the procedure is repeated, wherein the parameter for the capacity in the battery model is set to the determined value (“model update”). This results in an iterative approximation to the real value of the capacity.

In the following, the procedure described is demonstrated using the experimental data already mentioned, specifically using all three data sets (full cycles, partial cycles, driving cycles). The simple equivalent circuit model of FIG. 3a) is used. The serial resistance is set to the reference value of Rₛ=4,579 mΩ, the open-circuit voltage curve is set to the reference curve shown in FIG. 4. Any starting values are selected for the capacitance, in this example different values for the three data sets examined.

Results for full cycles are shown in FIG. 12. C=30 Ah is used as the starting value for the capacity assumed in the model. A charge/discharge cycle is selected as the time period T (approx. 2.1 h), the algorithm is applied after every four time periods T₁ to T₄, as an example of continuous use of the experimental time series. FIG. 12a) shows the experimentally measured voltage. This data serves as the input variable for the voltage-guided model. FIG. 12b) shows the measured current Iₘₑₛₛ and the current simulated with the model I_{mod}. In the period T₁ (between 0 and 2 h), this deviates significantly from the experimental measured value. This is a sign that the capacity of C=30 Ah assumed in the model is incorrect. FIG. 12d) shows the values for the capacity determined using the method, based on the assumed initial capacity, here as a function of the updates carried out. After a period T₁ of around 2 hours, the capacity was determined for the first time; the value is already very close to the reference value. In the second period T₂, the deviation between the simulated and experimental current shown in FIG. 12b) is further reduced, while the quotient ΔC in FIG. 12c) approaches one. At the end of the data set, after a good eight hours of measurement with four full cycles and four updates, the reference value is reached.

FIG. 13 shows results using the same procedure, but based on experimental partial cycles; here the battery was cycled between 25% and 75% state of charge. Equal time periods T₁ to T₄ of around 2 hours each are selected, corresponding to 2 partial cycles. C=2 Ah is used as the starting value for the capacity assumed in the model. Here too, the reference value for the capacity is reached at the end of the measurement series, which lasts a good eight hours in total.

FIG. 14 shows results for experimental driving cycles. The entire data set of just over eight hours shown is used here as the time period T. C=10 Ah is used as the starting value for the capacity assumed in the model. The algorithm is applied to this data several times and the model parameter is updated each time. The reference value is reached after four such updates.

The new method for determining the capacity of a rechargeable battery was successfully demonstrated on the basis of each of the data sets shown and its high flexibility with regard to input data and starting values was demonstrated.

### Simultaneous Determination of Internal Resistance and Open-Circuit Voltage Curve

The internal resistance and open-circuit voltage curve can be determined simultaneously by combining the approaches used to determine the internal resistance and the open-circuit voltage curve. The voltage difference due to the internal resistance ΔV_{R} according to Eq. (8) (FIG. 6) and the voltage difference due to the open-circuit voltage curve ΔV⁰ according to Eq. (21) (FIG. 10) are combined to a total difference ΔVₜₒₜ (the index “tot” for total) according to

$${ΔV}_{tot} = {ΔV}^{0} - Δ R \cdot {I}_{mess} . \qquad ( 40 )$$

Analogous to Eq. (15) and (27), the following expression can be derived:

$$\frac{d}{dt} ( \frac{{ΔV}_{tot}}{b} ) = - \frac{{I}_{mod} - {I}_{mess}}{C} . \qquad ( 41 )$$

The discretization results in

$${ΔV}_{tot , n} = - \frac{Δ t \cdot {b}_{n}}{C} ( {I}_{mod , n} - {I}_{mess , n} ) + \frac{{ΔV}_{tot , n - 1} \cdot {b}_{n}}{{b}_{n - 1}} . \qquad ( 42 )$$

This equation allows the calculation of ΔVₜₒₜ from discrete time series of Iₘₑₛₛ and I_{mod}. A value of ΔVₜₒₜ is obtained for each time step. Eq. (40) can be used to calculate ΔV⁰ and ΔR in a subsequent step. To do this, ΔVₜₒₜ is averaged section by section over a matrix of DOD and Iₘₑₛₛ. For each DOD section, a linear fit of ΔVₜₒₜ against Iₘₑₛₛ is performed according to Eq. (40). The y-axis intercept yields ΔV⁰(DOD), the slope yields ΔR(DOD). The latter value can be averaged over all DODs if required.

The battery properties to be determined R_{cal} and

$${V}_{cal}^{0}$$

are the determined analogously to equations (19) and (30). Finally, an update of the model parameters can be carried out analogous to equations (20) and (31).

The simultaneous determination of internal resistance and open-circuit voltage curve is carried out in practice in the following steps. First, a voltage-controlled battery model with a known parameter value for the capacity C_{mod} is provided. An arbitrary starting value is assumed for the parameter(s) associated with the internal resistance R_{mod} (e.g. Rₛ for the simple equivalent circuit model in FIG. 3a) and for the course of the open-circuit voltage curve

$${V}_{mod}^{0} ( DOD )$$

(it makes sense to assume a linear course between the charge and discharge end voltages here). The battery is operated over a period of time T with measurement of current Iₘₑₛₛ and voltage Vₘₑₛₛ. The simulated current I_{mod} is then calculated over the period T using the voltage-controlled model. This is followed by the calculation of ΔVₜₒₜ according to equation (42). The values ΔVₜₒₜ are averaged section by section in a matrix of DOD and Iₘₑₛₛ sections to the mean value Δ̅V̅ₜ̅ₒ̅ₜ̅ (DOD, Iₑₓₚ) over the period T. Subsequently, ΔV⁰(DOD) and ΔR(DOD) are calculated according to Eq. (40) by linear regression of Δ̅V̅ₜ̅ₒ̅ₜ̅(DOD, Iₘₑₛₛ) against Iₘₑₛₛ for each DOD section. Subsequently, ΔR(DOD) is averaged over all DOD to Δ̅R̅. The approximate value for the real internal resistance R_{cal} is then calculated according to Eq. (19) and the approximate value for the real open-circuit voltage curve

$${V}_{cal}^{0} ( DOD )$$

according to Eq. (30). Optionally, the procedure is repeated, wherein the parameter(s) associated with the internal resistance R_{mod} and the open-circuit voltage curve

$${V}_{mod}^{0}$$

in the battery model are set to the values determined (“model update”). This results in an iterative approximation to the real values of the internal resistance and open-circuit voltage curve.

The averaging of ΔVₜₒₜ can also be carried out section by section for different measured temperatures. The value ΔR(DOD) does not necessarily have to be averaged over all DODs. This can be used to determine values for the internal resistance R(DOD, I, ϑ) and the open-circuit voltage curve V⁰(DOD, ϑ) that are dependent on the state of charge, current and/or temperature.

In the following, the procedure described is demonstrated using the experimental data already mentioned, specifically using the full cycles (FIG. 5). The simple equivalent circuit model of FIG. 3a) is used. The battery model is given an arbitrary starting value for the serial resistance, here Rₛ=9 mΩ. The open-circuit voltage curve V⁰(DOD) is also set to an arbitrary starting value, namely a linear curve between the two final voltages. The capacitance is set to the reference value of C=19.96 Ah. A charge/discharge cycle is selected as the time period T (approx. 2.1 h).

The results are shown in FIG. 15. FIG. 15a) shows the measured voltage Vₘₑₛₛ as an input variable for the voltage-controlled model. FIG. 15b) shows both the measured current Iₘₑₛₛ and the simulated current I_{mod} from the voltage-controlled model. In the period T₁ (between 0 and 2 h), a clear deviation I_{mod}−Iₘₑₛₛ of the two curves can be seen. FIG. 15c) shows the difference between the simulated and experimental voltage ΔVₜₒₜ determined according to Eq. (2) using the data shown in FIG. 15b). The value ΔVₜₒₜ varies over time during the period T₁ (between 0 and 2 h). Over the first cycle duration T₁, these values are averaged section by section in a matrix for each DOD percentage point and each current Iₘₑₛₛ(to whole amperes). For each individual DOD section, a linear regression of the course ΔVₜₒₜ against Iₘₑₛₛ is carried out and the values ΔV⁰(DOD) and ΔR(DOD) are calculated from this using Eq. (40). The latter value is averaged over the entire DOD section to Δ̅R̅. Finally, the model parameters are set to the new values according to Eqs. (20) and (31). The procedure is repeated for the time periods T₂ to T₄. The internal resistances determined in this way are shown in FIG. 15d), starting from the assumed initial value. The process stabilizes after three cycles close to the reference value. The open-circuit voltage curves determined are shown in FIG. 15e). Here, too, the method stabilizes close to the reference curve after three cycles. At the same time, the prediction quality of the voltage-guided model improves (see FIG. 15b) for time periods >2 h) and thus ΔVₜₒₜ becomes smaller (see FIG. 15c) for time periods >2 h).

With these results, the new method for the simultaneous determination of the internal resistance and open-circuit voltage curve of a rechargeable battery was successfully demonstrated.

### Simultaneous Determination of Internal Resistance and Capacitance

The methods described above for determining capacitance and internal resistance can be combined. This allows these two parameters to be determined simultaneously. No new theoretical development is required for this, only a combination of the practical implementations.

The simultaneous determination of capacity and internal resistance is carried out in practice in the following steps. First, a voltage-controlled battery model with known parameter values for the open-circuit voltage curve

$${V}_{mod}^{0} ( DOD )$$

is provided. Arbitrary starting values are assumed for the capacity C_{mod} and the parameter(s) associated with the internal resistance R_{mod} (e.g. Rₛ for the simple equivalent circuit model in FIG. 3a). The battery is operated over a period of time T with measurement of current Iₘₑₛₛ and voltage Vₘₑₛₛ. The simulated current I_{mod} is then calculated over the period T using the voltage-controlled model. This is followed by the calculation of ΔR according to equation (17). The values for ΔR are averaged over the time period T to the mean value Δ̅R̅. Subsequently, ΔC is calculated according to Eq. (37). The approximate value for the real internal resistance R_{cal} is then calculated according to Eq. (19) and the approximate value for the real capacitance according to Eq. (38). Optionally, the procedure is repeated, wherein the capacitance C_{mod} and the parameter(s) associated with the internal resistance R_{mod} in the battery model are set to the determined values (“model update”). This results in an iterative approximation to the real values of capacitance and internal resistance.

The averaging of ΔR can also be carried out section by section for different ranges of the depth of discharge DOD, different measured temperatures or different current levels Iₘₑₛₛ. This allows a charge state, current and/or temperature-dependent internal resistance R(DOD, I, ϑ) to be determined.

In the following, the procedure described is demonstrated using the experimental data already mentioned, namely the full cycles (FIG. 5) and the partial cycles. The simple equivalent circuit model of FIG. 3a) is used. The battery model is given the measured open-circuit voltage curve V⁰(DOD) as shown in FIG. 4. The capacity is set to an arbitrary starting value, here C=30 Ah for the full cycles and C=2 Ah for the partial cycles as an example. The parameter for the serial resistance is also set to an arbitrary starting value, in this example to Rₛ=1 mΩ.

FIG. 16 shows the results for the full cycles. A charge/discharge cycle is selected as the time period T (approx. 2.1 h). FIG. 16c) and FIG. 16d) show that the capacity and internal resistance converge towards the reference value after just three model updates (i.e. after three full cycles). FIG. 17 shows analogous results for the partial cycles. A partial charge/discharge cycle is selected here as the time period T (approx. 1 h). FIG. 17c) and FIG. 17d) show that the capacitance and internal resistance converge towards the reference value after around ten model updates (i.e. after ten partial cycles). These results demonstrate the successful use of the new method for the simultaneous determination of internal resistance and capacitance.

### Simultaneous Determination of Open-Circuit Voltage Curve and Capacitance

The methods described above for determining the capacitance and open-circuit voltage curve can be combined. This allows these two parameters to be determined simultaneously. No new theoretical development is required for this, only a combination of the practical implementations.

The simultaneous determination of capacity and open-circuit voltage curve is carried out in practice in the following steps. First, a voltage-controlled battery model with known parameter values is provided for the parameter(s) associated with the internal resistance R_{mod} (e.g. Rₛ for the simple equivalent circuit model in FIG. 3a). Any initial values are assumed for the capacity C_{mod} and for the course of the open-circuit voltage curve

$${V}_{mod}^{0} ( DOD )$$

(it makes sense to assume a linear course between the final charge and discharge voltages). The battery is operated over a period of time T with measurement of current Iₘₑₛₛ and voltage Vₘₑₛₛ. The simulated current I_{mod} is then calculated over the period T using the voltage-controlled model. This is followed by the calculation of ΔV⁰ according to equation (29). The values for ΔV⁰ are averaged section by section for DOD areas to the mean value Δ̅V̅⁰̅(DOD) over the period T. Subsequently, ΔC is calculated according to Eq. (37). The approximate values for the real open-circuit voltage curve

$${V}_{cal}^{0} ( DOD )$$

are then calculated according to Eq. (30) and for the real capacitance C_{cal} according to Eq. (38). Optionally, the procedure is repeated, wherein the capacity C_{mod} and the open-circuit voltage curve

$${V}_{m o d}^{0}$$

in the battery model are set to the values determined (“model update”). This results in an iterative approximation to the real values of the capacitance and open-circuit voltage curve.

In the following, the procedure described is demonstrated using the experimental data already mentioned, specifically using a full cycle. The simple equivalent circuit model from FIG. 3a) is used. The capacitance is set to an arbitrary starting value, here C=10 Ah as an example. The open-circuit voltage curve V⁰(DOD) is also set to an arbitrary starting value, namely a linear curve between the two final voltages. The parameter for the serial resistance is set to the reference value of Rₛ=4,579 mΩ. A charge/discharge cycle is selected as the time period T (approx. 2.1 h). The procedure is applied a total of nine times over this period and a model update is carried out each time. The results are shown in FIG. 18. FIG. 18c) shows that the capacity converges towards the reference value after just three model updates. FIG. 18d) shows that the determination of the open-circuit voltage curve requires further updates; here the reference value is reached after nine updates. These results demonstrate the successful use of the new method for the simultaneous determination of the open-circuit voltage curve and capacity of a rechargeable battery.

### Simultaneous Determination of Capacitance, Internal Resistance and Open-Circuit Voltage Curve

The methods described above for determining the capacity, internal resistance and open-circuit voltage curve can be combined. This allows the simultaneous, complete characterization of all relevant parameters of an unknown battery. No new theoretical development is required for this, only a combination of practical implementations.

The simultaneous determination of capacity, internal resistance and open-circuit voltage curve is carried out in practice in the following steps. First, a voltage-controlled battery model is provided. Any starting values are assumed for the capacity C_{mod}, the parameter(s) associated with the internal resistance R_{mod} (e.g. Rₛ for the simple equivalent circuit model in FIG. 3a) and for the course of the open-circuit voltage curve

$${V}_{m o d}^{0} ( DOD )$$

(it makes sense to assume a linear course between the charging and discharging end voltages). The battery is operated over a period of time T with measurement of current Iₘₑₛₛ and voltage Vₘₑₛₛ. The simulated current I_{mod} is then calculated over the period T using the voltage-controlled model. This is followed by the calculation of ΔVₜₒₜ according to equation (42). The values for ΔVₜₒₜ are averaged in a matrix of DOD and Iₘₑₛₛ sections to the mean value Δ̅V̅ₜ̅ₒ̅ₜ̅(DOD, Iₘₑₛₛ) over the period T. ΔV⁰(DOD) and ΔR(DOD) are calculated according to Eq. (40) by linear regression of Δ̅V̅ₜ̅ₒ̅ₜ̅ (DOD, Iₘₑₛₛ) against Iₘₑₛₛ for each DOD section. The values ΔR(DOD) are averaged over all DOD to Δ̅R̅. ΔC is calculated according to Eq. (37). The approximate values for the real internal resistance are then calculated according to Eq. (19), for the real open-circuit voltage curve according to Eq. (30) and for the real capacitance according to Eq. (38). Optionally, the procedure is repeated, wherein the capacitance C_{mod} and the parameter(s) associated with the internal resistance R_{mod} and the open-circuit voltage curve

$${V}_{m o d}^{0}$$

are set to the determined values in the battery model (“model update”). This results in an iterative approximation to the real values of the capacitance, internal resistance and open-circuit voltage curve.

In the following, the procedure described is demonstrated on the basis of the experimental data, using a full cycle. The simple equivalent circuit model in FIG. 3a) is used. The battery model is given arbitrary starting values for the capacity of C=10 Ah and for the parameter associated with the internal resistance of Rₛ=9 mΩ. The open-circuit voltage curve V⁰(DOD) is also set to an arbitrary starting value, namely a linear curve between the two final voltages. A charge/discharge cycle is selected as the time period T (approx. 2.1 h). The procedure is applied a total of 19 times over this period and a model update is carried out each time. The results are shown in FIG. 19. FIG. 19a) and FIG. 19b) show the voltage and current of the battery over the period T. The determined values of capacity, internal resistance and open-circuit voltage curve as a function of the continuous model updates are shown in FIG. 19c), FIG. 19d) and FIG. 19e), in each case starting from the initial values. The dashed lines are the independently determined reference values. After 19 model updates, all three parameters (capacitance, internal resistance and open-circuit voltage curve) converge towards the reference values. With these results, the new method for the simultaneous determination of internal resistance, open-circuit voltage curve and capacity of a rechargeable battery was successfully demonstrated. The method thus allows the complete characterization of all relevant parameters of an unknown battery.

### LIST OF ESSENTIAL NAMES OF VARIABLES AND PARAMETERS

C Capacity of the battery
C_{mod} Initial value in the battery model for the capacity
C_{cal} Calculated value for the capacity
ΔC Deviation between initial value of capacitance and calculated value of capacitance
Iₘₑₛₛ(t) Measured battery current
I_{mess,n} Recorded value of the battery current at the time n
I_{mod}(t) Model battery current
I_{mod,n} Simulated current of the battery model at the time n
Vₘₑₛₛ(t) Measured battery voltage
V mess,n Recorded value of the battery voltage at the time n
V⁰ Open-circuit voltage curve
V⁰ₘₑₛₛ Measured open-circuit voltage curve
V⁰_{mod} Initial value in the battery model for the open-circuit voltage curve
V⁰_{cal} Calculated value for the open-circuit voltage curve
ΔV⁰ Deviation between the initial value of the open-circuit voltage curve and the calculated value of the open-circuit voltage curve
ΔV⁰ₙ Discrete-time values of the difference in the open-circuit voltage curve
ΔVₜₒₜ Total voltage difference
ΔV_{tot,n} Discrete values of the total difference
Δ̅V̅⁰̅ Average value of the difference of the open-circuit voltage curve
V⁰(DOD, ϑ) Open-circuit voltage curve as a function of discharge depth and/or temperature
b Slope of the open-circuit voltage curve
R Internal resistance
R_{mod} Initial value in the battery model for the internal resistance
R_{cal} Calculated value for the internal resistance
ΔR Deviation between the initial value of the internal resistance and the calculated value of the internal resistance
ΔRₙ Discrete-time values of the difference in internal resistance
Δ̅R̅ Average value of the difference in internal resistance
R(DOD, I, ϑ) Internal resistance as a function of discharge depth and/or current and/or temperature
SOC State of charge
DOD Depth of discharge
t time
t Sampling interval
T (measuring) Period
ϑ Temperature
BMS Battery management system

### LIST OF REFERENCE SYMBOLS

100 Total algorithm
102 First component of the overall algorithm
104 second component of the overall algorithm
106 Battery
110 Unit for voltage measurement
112 Unit for current measurement
114 Load
116 Display unit
118 Computing unit
120 Evaluation and control unit

1. A method for determining the internal resistance and/or the open-circuit voltage curve and/or the capacity of a rechargeable battery (106), the method comprising the steps of:
(a) Creation of a dynamic, voltage-controlled, mathematical battery model, wherein predetermined initial values V⁰_{mod}, R_{mod}, C_{mod} are used for the internal resistance R and/or the open-circuit voltage curve V⁰ and/or the capacitance C;
(b) Acquisition of time-discretely measured values for the battery current Iₘₑₛₛ(t) and the battery voltage Vₘₑₛₛ(t) of the rechargeable battery over a specified period of time T;
(c) Using the measured values for the battery voltage Vₘₑₛₛ(t) as an input variable for the dynamic, voltage-controlled, mathematical battery model and calculating values for a simulated current I_{mod}(t) as an output variable of the battery model; and
(d) Determination of calculated values for the internal resistance R_{cal} and/or the open-circuit voltage curve V⁰_{cal} and/or the capacitance C_{cal}, in each case using the values for the simulated current I_{mod}(t) and the measured values for the current Iₘₑₛₛ(t), in each case using a predefined calculation rule.

2. Method according to claim 1, characterized in that
(a) the method comprises at least two iteration steps;
(b) wherein each iteration step comprises performing steps (a) to (d) of the method according to claim 1; and
(c) wherein in each iteration step, except the first, the calculated values for the internal resistance R_{cal} and/or the open-circuit voltage curve V⁰_{cal} and/or the capacitance C_{cal} determined in step (d) of the previous iteration step are used in place of the initial values R_{mod}, V⁰_{mod} and C_{mod} for the internal resistance R and/or the open-circuit voltage curve V⁰ and/or the capacitance C determined in step (d) of the previous iteration step.

3. Method according to claim 1 or 2, characterized in that
(a) the method comprises at least two iteration steps;
(b) wherein each iteration step comprises performing steps (a), (c) and (d) of the method according to claim 1; and
(c) wherein in each iteration step, except the first, the calculated values for the internal resistance R_{cal} and/or the open-circuit voltage curve V⁰_{cal} and/or the capacitance C_{cal} determined in step (d) of the previous iteration step are used in place of the initial values R_{mod}, V⁰_{mod} and C_{mod} for the internal resistance R and/or the open-circuit voltage curve V⁰ and/or the capacitance C determined in step (d) of the previous iteration step.

4. Method according to any one of claims 1 to 3, wherein
(a) deviations ΔR, ΔV⁰, ΔC between the respective predetermined initial values R_{mod}, V⁰_{mod}, C_{mod} and the respective calculated values R_{cal}, V⁰_{cal}, C_{cal} are calculated using a deviation between the values for the simulated current intensity I_{mod}(t) and the measured values for the battery current Iₘₑₛₛ(t); and
(b) the calculated values for internal resistance R_{cal} and/or open-circuit voltage curve V⁰_{cal} and/or capacitance C_{cal} are calculated from the deviations ΔR, ΔV⁰, ΔC determined in this way and the specified initial values R_{mod}, V⁰_{mod}, C_{mod} for internal resistance R and/or open-circuit voltage curve V⁰ and/or capacitance C_{cal}.

5. Method according to one of claims 1 to 4, characterized in that the following calculation rule is used to determine the internal resistance R:
$$\frac{d}{d t} ( \frac{Δ R \cdot {I}_{m e s s}}{b} ) = \frac{{I}_{mod} - {I}_{m e s s}}{C} ,$$
wherein ΔR is the difference between the internal resistance of the battery model R_{mod} and the calculated value for the internal resistance R_{cal}, b is the slope of the open-circuit voltage curve, I_{mod} is the current of the battery model and Iₘₑₛₛ is the detected current of the battery.

6. Method according to one of claims 1 to 4, characterized in that the following calculation rule is used to determine the open-circuit voltage curve V⁰:
$$\frac{d}{d t} ( \frac{Δ {V}^{0}}{b} ) = - \frac{{I}_{mod} - {I}_{m e s s}}{C} ,$$
wherein ΔV⁰ is the difference between the open-circuit voltage curve of the battery model
$${V}_{m o d}^{0}$$
and the calculated value for the open-circuit voltage curve
$${V}_{cal}^{0} ,$$
b is the slope of the open-circuit voltage curve, I_{mod} is the current of the battery model and Iₘₑₛₛ is the detected current of the battery.

7. Method according to one of claims 1 to 4, characterized in that the following calculation rule is used to determine the capacitance C:
$$Δ C = \frac{{\int }_{t = 0}^{T} \vert {I}_{mod} ( t ) \vert dt}{{\int }_{t = 0}^{T} \vert {I}_{mess} ( t ) \vert dt} ,$$
wherein ΔC is the quotient of the capacity of the battery model C_{mod} and the calculated value for the capacity of the battery C_{cal}, I_{mod} is the amperage of the battery model and Iₘₑₛₛ is the detected amperage of the battery.

8. Method according to one of claims 1 to 4, characterized in that the following calculation rule is used for the simultaneous determination of the internal resistance R and the open-circuit voltage curve V⁰:
$$\frac{d}{d t} ( \frac{Δ {V}_{t o t}}{b} ) = - \frac{{I}_{m o d} - {I}_{m e s s}}{C}$$
$$with$$
$${ΔV}_{t o t} = Δ {V}^{0} - Δ R \cdot {I}_{m e s s} ,$$
wherein ΔVₜₒₜ is the total voltage difference, ΔV⁰ is the difference between the open circuit voltage curve of the battery model
$${V}_{m o d}^{0}$$
and the calculated value for the open circuit voltage curve
$${V}_{cal}^{0} ,$$
ΔR is the difference between the internal resistance of the battery model R_{mod} and the calculated value for the internal resistance R_{cal}, b is the slope of the open circuit voltage curve, I_{mod} is the current of the battery model and Iₘₑₛₛ is the detected current of the battery.

9. Method according to claims 5 to 8, characterized in that a numerical solution method is used for the calculation of the time-discrete values of the difference of the internal resistance ΔRₙ and/or the time-discrete values of the difference of the open-circuit voltage curve
$${Δ V}_{n}^{0}$$
and/or for the time-discrete values of the total voltage difference ΔV_{tot,n} and/or for the value of the quotient ΔC from the capacity of the battery model C_{mod} and the calculated value for the capacity of the battery C_{cal}.

10. Method according to claims 4 to 9, characterized in that at least two time-discrete values of the difference of the internal resistance ΔRₙ to an average value of the difference of the internal resistance Δ̅R̅ and/or at least two time-discrete values of the difference of the open-circuit voltage curve
$$Δ {V}_{n}^{0}$$
to an average value of the difference of the open-circuit voltage curve Δ̅V̅⁰̅ are averaged over a measurement period T.

11. Method according to claims 1 to 10, characterized in that the internal resistance is determined as a function of discharge depth and/or current intensity and/or temperature R(DOD, I, ϑ),
wherein several mean values of the difference of the internal resistance Δ̅R̅ are used for the determination, and
wherein the mean values of the difference in internal resistance Δ̅R̅ are determined by averaging values of the difference in internal resistance ΔRₙ over the measurement period T section by section over various ranges of the depth of discharge DOD and/or current I and/or temperature ϑ.

12. Method according to claims 1 to 9, characterized in that the open-circuit voltage curve is determined as a function of the depth of discharge and/or the temperature V⁰(DOD, ϑ),
wherein several mean values of the open-circuit voltage curve Δ̅V̅⁰̅ are used for the determination, and
wherein the mean values of the open-circuit voltage curve Δ̅V̅⁰̅ are determined by averaging values of the open-circuit voltage curve
$$Δ {V}_{n}^{0}$$
over the measurement period T section by section over different ranges of the depth of discharge (DOD) and/or the temperature ϑ.

13. Device for determining the internal resistance and/or the open-circuit voltage curve and/or the capacity of a rechargeable battery (106), having an evaluation and control unit (120) which comprises a detection device for detecting measured values for the battery current Iₘₑₛₛ(t) and the battery voltage Vₘₑₛₛ(t) and/or the temperature ϑₘₑₛₛ(t) (110, 112) of the rechargeable battery, preferably at equidistant time intervals Δt or at predetermined points in time, and a computing unit (118) into which the detected measured values can be fed, characterized in that the evaluation and control device (120) is designed to carry out the method according to one of claims 1 to 12.

14. Computer program for determining the internal resistance and/or the open-circuit voltage curve and/or the capacity of a rechargeable battery (106), characterized in that the computer program is designed in such a way that when the computer program is run in a data processing unit, in particular in the evaluation and control device according to claim 13, the method according to one of claims 1 to 12 is carried out.
